(19) United States
(12) Patent Application Publication
(10) Pub. No.: US 2017/0111990 A1
(43) Pub. Date: Apr. 20, 2017

(54) PRINTED CIRCUIT BOARD INCLUDING BENDING REGION

(71) Applicant: Samsung Electronics Co., Ltd., Suwon-si (KR)

(72) Inventor: Ho-hyeuk IM, Seoul (KR)

(73) Assignee: Samsung Electronics Co., Ltd., Suwon-si (KR)

(21) Appl. No.: 15/249,931

(22) Filed: Aug. 29, 2016

(30) Foreign Application Priority Data
Oct. 20, 2015 (KR) 10-2015-0146094

(51) Int. Cl. H05K 1/02; H05K 1/11

(52) U.S. Cl. CPC H05K 1/0281; H05K 1/0278; H05K 1/118; H05K 1/0298; H05K 1/116; H05K 1/111

(57) ABSTRACT

A printed circuit board (PCB) that may improve the reliability of an electronic apparatus includes a base substrate having a first edge and a second edge on both sides of the base substrate, the base substrate having a bending region including an opening adjacent to the first edge, an opening adjacent to the second edge, and mounting regions extending from both ends of the bending region and including device mounting portions, a connection line formed on the base substrate and crossing the bending region, the connection line configured to connect the device mounting portions of the mounting regions extending from the both ends of the bending region; and a guard pattern formed on each or at least one of a top surface and a bottom surface of the base substrate along a boundary of each or at least one of the openings.

### CROSS-REFERENCE TO RELATED APPLICATION

This application claims the benefit of priority from Korean Patent Application No. 10-2015-0146094, filed on Oct. 20, 2015, in the Korean Intellectual Property Office, the disclosure of which is incorporated herein in its entirety by reference.

### BACKGROUND

The inventive concepts relate to a printed circuit board (PCB), and more particularly, to a flexible PCB including a bending region that is repeatedly bent.

As the electronic industry has greatly advanced. and requirements of users have increased, electronic apparatuses have been smaller and various types of wearable devices have been developed. Since wearable devices typically have curved surfaces in order to be worn on a human body, or are repeatedly bent in order to be attached or detached to or from the human body, the wearable devices include flexible PCBs.

### SUMMARY

The inventive concepts provide a printed circuit board (PCB) including a bending region that may improve the reliability of an electronic apparatus that is repeatedly bent when being used.

According to an example embodiment of the inventive concepts, a printed circuit board (PCB) includes a base substrate having a first edge and a second edge on both sides of the base substrate, the base substrate having a bending region including an opening adjacent to the first edge, an opening adjacent to the second edge, and mounting regions extending from both ends of the bending region and including device mounting portions, a connection line formed on the base substrate and crossing the bending region, the connection line configured to connect the device mounting portions of the mounting regions extending from, both ends of the bending region, and a guard pattern formed on one or more of a top surface and a bottom surface of the base substrate along a boundary of one or more of the openings.

According to another example embodiment of the inventive concepts, a printed circuit board (PCB) includes a base substrate having a first edge and a second edge on both sides of the base substrate, the base substrate having a bending region that includes at least one pair of openings respectively adjacent to the first edge and the second edge and facing each other and mounting regions that extend from both ends of the bending region and include device mounting portions, a connection line formed on the base substrate and crossing bending region, the connection line configured to connect the device mounting portions of the mounting regions that extend from the both ends of the bending region, and a guard pattern formed on each or at least one of a top surface and a bottom surface of the base substrate along a boundary of each or at least one of the openings.

According to another example embodiment of the inventive concepts, a printed circuit board (PCB) includes a base substrate including at least one opening in at least one edge thereof in a bending region configured to be bent, at least one guard pattern along a boundary of the at least one opening, and a connection line on the base substrate and crossing the bending region, the connection line electrically connecting at least two portions on opposite sides of the bending region.

### BRIEF DESCRIPTION OF THE DRAWINGS

Example embodiments of the inventive concepts will be more clearly understood from the following detailed description taken in conjunction with the accompanying drawings in which:

FIG. 1 is a schematic view for explaining an electronic apparatus and a printed circuit board (PCB), according to an example embodiment;

FIG. 2 is a plan view illustrating parts of a PCB, according to an example embodiment;

FIG. 3 is a plan view illustrating parts of a PCB, according to an example embodiment;

FIG. 4 is a plan view illustrating parts of a PCB, according to an example embodiment;

FIG. 5 is a plan view illustrating parts of a PCB, according to an example embodiment;

FIG. 6 is a plan view illustrating parts of a PCB, according to an example embodiment;

FIG. 7 is a plan view illustrating parts of a PCB, according to an example embodiment;

FIG. 8 is a plan view illustrating parts of a PCB, according to an example embodiment;

FIG. 9 is a plan view illustrating parts of a PCB, according to an example embodiment;

FIG. 10 is a plan view illustrating parts of a PCB, according to an example embodiment;

FIG. 11 is a plan view illustrating parts of a PCB, according to an example embodiment;

FIG. 12 is a plan view illustrating parts of a PCB, according to an example embodiment;

FIG. 13 is a plan view illustrating parts of a PCB, according to an example embodiment;

FIG. 14 is a plan view illustrating parts of a PCB, according to an example embodiment;

FIG. 15 is a plan view illustrating parts of a PCB, according to an example embodiment;

FIG. 16 is a plan view illustrating parts of a PCB, according to an example embodiment;

FIG. 17 is a plan view illustrating parts of a PCB, according to an example embodiment;

FIG. 18A is a partial enlarged cross-sectional view of a PCB, according to an example embodiment;

FIG. 18B is a partial enlarged cross-sectional view of a PCB, according to an example embodiment;

FIG. 18C is a partial enlarged cross-sectional view of a PCB, according to an example embodiment;

FIG. 18D is a partial enlarged cross-sectional view of a PCB, according to an example embodiment;

FIG. 18E is a partial enlarged cross-sectional view of a PCB 10-5 according to an example embodiment.

FIG. 18F is a partial enlarged cross-sectional view of a PCB, according to an example embodiment;

FIG. 19 is a schematic view for explaining an electronic apparatus and the PCB, according to an example embodiment;

FIG. 20A is a partial enlarged cross-sectional view of a PCB, according to an example embodiment;

FIG. 20B is a partial enlarged cross-sectional view of a PCB, according to an example embodiment;

FIG. 21 is a block diagram illustrating a configuration of a system according to an example embodiment; and

FIG. 22 is a cross-sectional view of an electronic apparatus according to an example embodiment.

### DETAILED DESCRIPTION OF THE EMBODIMENTS

The inventive concepts will now be described more fully with reference to the accompanying drawings, in which embodiments are shown.

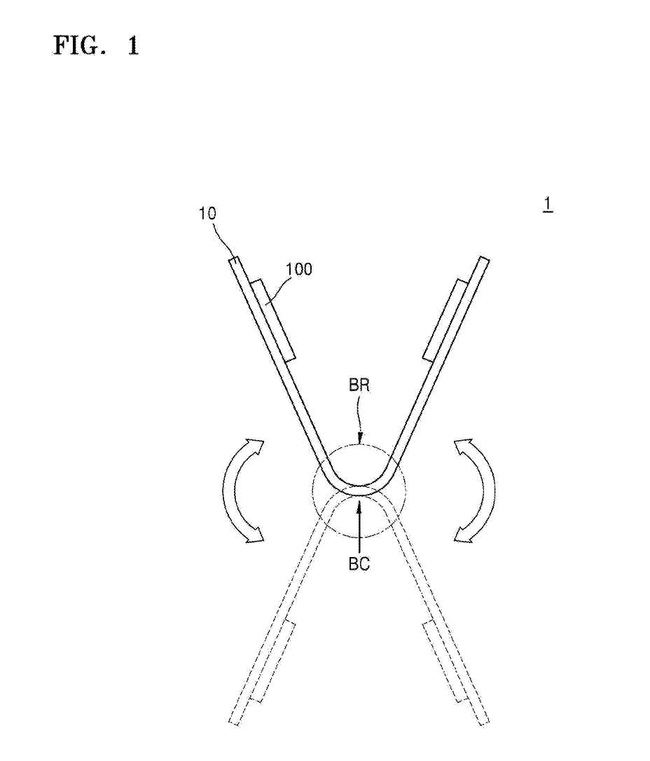

FIG. 1 is a schematic view for explaining an electronic apparatus 1 and a printed circuit board (PCB) 10, according to an example embodiment.

Referring to FIG. 1, the electronic apparatus 1 includes the PCB 10 and a device 100 mounted on the PCB 10.

The PCB 10 may be a flexible PCB. The PCB 10 may include a base substrate, a connection line, and a cover layer that is an insulating layer and covers each of, or at least one of, both surfaces of the base substrate.

The base substrate may be a flexible film formed of or include a high durability material. The base substrate may be formed of or include, for example, a polyimide (PI) film, a polyester (PET) film, polyester terephthalate, thin glass-epoxy, fluorinated ethylene propylene (FEP), resin-coated paper, liquid polyimide resin, a polyethylene naphthalate (PEN) film, or a liquid crystalline polymer (LCP) film.

The connection line may be formed of or include, for example, an electrolytically deposited (ED) copper foil, a rolled-annealed (RA) copper foil, a stainless steel foil, an aluminum foil, an ultra-thin copper foil, sputtered copper, or a copper alloy. The connection line may be formed on one surface or on both surfaces of the base substrate, or may be formed on both surfaces of the base substrate and in the base substrate. When the connection line is formed on both surfaces of the base substrate, or may be formed on both surfaces and in the base substrate to form a plurality of layers, the connection line may further include a portion that connects adjacent connection lines on different layers.

The cover layer may be formed of or include, for example, a PI film, a PET film, a flexible solder mask, a photoimageable coverlay (PIC), or a photo-imageable solder resist. The cover layer may be formed, for example, by directly coating the base substrate with thermosetting ink by using silk-screen printing or inkjet printing and subsequently performing thermal curing. The cover layer may be formed, for example, by substantially entirely coating the base substrate with a photo-imageable solder resist by using screen printing or spray printing, removing any unnecessary portion through exposure and development, and performing thermal curing. The cover layer may be formed, for example, by laminating a PI film or a PET film onto the base substrate.

The device 100 may be an electrical/electronic component (e.g., a semiconductor chip, an active device, a passive devices, a display device, a sound device, an input device, or a power supply) used to drive the electronic apparatus 1.

The semiconductor chip may include, for example, a semiconductor device formed on a semiconductor substrate. The semiconductor substrate may include, for example, silicon (Si). Alternatively, the semiconductor substrate may include a semiconductor element such as germanium (Ge), or a compound semiconductor such as silicon carbide (SiC), gallium arsenide (GaAs), indium arsenide (InAs), or indium phosphide (InP).

The semiconductor device may include various types of individual devices. The various types of individual devices may include various microelectronic devices, for example, a metal-oxide-semiconductor field-effect transistor (MOSFET) such as a complementary metal-oxide-semiconductor (CMOS) transistor, an image sensor such as a system large scale integration (LSI) or a CMOS imaging sensor (CIS), a micro-electro-mechanical system (MEMS), a memory device such as a flash memory, a dynamic random-access memory (DRAM), a static RAM (SRAM), an electrically erasable programmable read-only memory (EEPROM), a parameter RAM (PRAM), a magnetoresistive RAM (MRAM), or a resistive (RRAM), an active device, and a passive device.

The device 100 included in the electronic apparatus 1 may be electrically connected to a connection line formed on the PCB 10. The device 100 may be mounted in various ways on the PCB 10 according to a type of the electronic apparatus 1. The device 100 may be electrically connected to the connection line formed on the PCB 10 via a bonding wire, a connection bump, or a solder.

The electronic apparatus 1 may be or include, for example, a wearable device. When the electronic apparatus 1 is used, a portion of the electronic apparatus 1 may be repeatedly bent. The electronic apparatus 1 may be or include, but is not limited to, for example, a watch-type wearable device, a wristband-type wearable device, or a glasses-type wearable device.

A portion of the PCB 10 corresponding to the portion of the electronic apparatus 1 that is repeatedly bent is referred to as a bending region BR. A portion of the PCB 10 other than the bending region BR may be referred to as a mounting region on which the device 100 is mounted. Since the mounting region of the PCB 10 is a portion on which repeated bending does not occur, or hardly occurs, when the electronic apparatus 1 is used, fatigue may not occur on the mounting region, and the reliability of the electronic apparatus 1 may not be affected by the mounting region.

When the electronic apparatus 1 is repeatedly bent during use, deformation in the bending region BR may be similar or the same on both surfaces of the PCB 10. For example, compressive and/or tensile deformation may occur on one surface of the PCB 10 and tensile and/or compressive deformation may occur on the other surface of the PCB 10. Accordingly, stress caused by fatigue may be substantially similar or the same on both surfaces of the PCB 10 included in the electronic apparatus 1.

A line that connects portions in the bending region BR on which the largest deformation, that is, the largest compression and/or tension, of the PCB 10 occurs when the electronic apparatus 1 is repeatedly bent during use may be referred to as a bending central line BC.

Although there may only be one bending region BR in FIG. 1, the example embodiment is not limited thereto, and there may be a plurality of bending regions BR according to a type of the electronic apparatus 1.

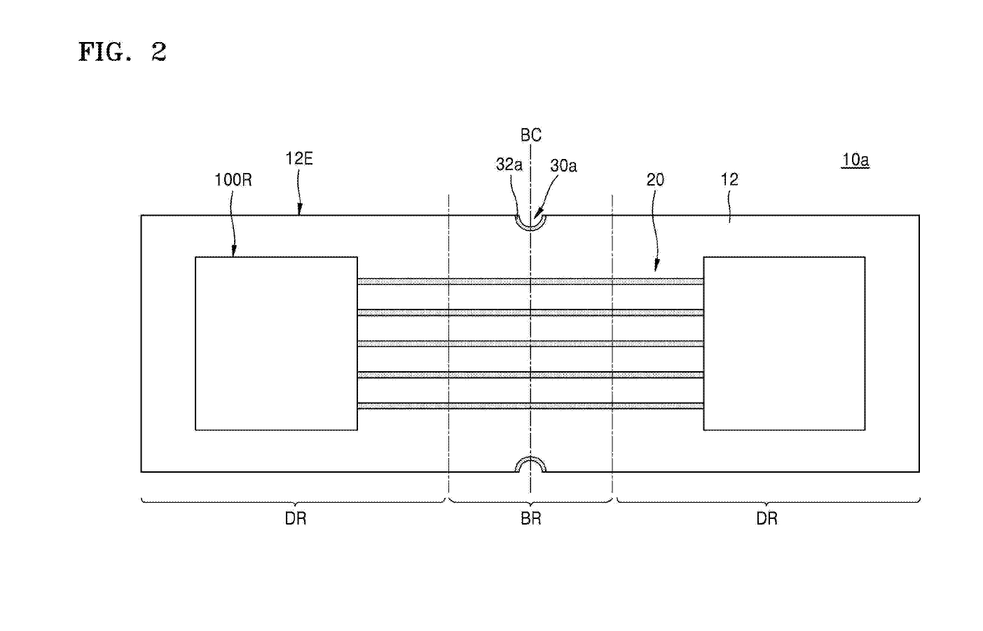

FIGS. 2 through 17 are plan views illustrating relevant parts of a PCB included in the electronic apparatus 1. In FIGS. 2 through 17, the same elements as those in FIG. 1 are denoted by the same reference numerals, and a repeated explanation thereof will not be given.

FIG. 2 is a plan view illustrating essential parts of a PCB 10a according to an example embodiment.

Referring to FIG. 2, the PCB 10a includes a base substrate 12 and a connection line 20 formed on the base substrate 12. The base substrate 12 included in the PCB 10a may include the bending region BR having edges 12E on both sides thereof and mounting regions DR extending from both ends of the bending region BR.

The bending region BR is a portion of the PCB 10a corresponding to a portion of the electronic apparatus 1 (see FIG. 1) including the PCB 10a that is repeatedly bent. The bending region BR is a part of the base substrate 12, and thus the edges 12E of the bending region BR may also be the edges 12E of the base substrate 12.

Each or at least one of the mounting regions DR may include a device mounting portion 100R on which the device 100 (see FIG. 1) is mounted. The connection line 20 may extend to the device mounting portion 100R, and may be electrically connected to the device 100 (see FIG. 1) mounted on the device mounting portion 100R.

Although the mounting region DR extending from each or at least one of both ends of the bending region BR includes one device mounting portion 100R, the example embodiment is not limited thereto. A plurality of the device mounting portions 100R may be formed according to the number of the devices 100 (see FIG. 1) included in the electronic apparatus 1 (see FIG. 1), and in this case, the connection line 20 may connect one device mounting portion 100R and at least another device mounting portion 100R.

That is, although the connection line 20 crosses the bending region BR and connects the device mounting portions 100R of two mounting regions DR extending from both ends of the bending region BR from among various connection lines formed on the base substrate 12, the connection line 20 included in the electronic apparatus 1 may be designed and arranged in various ways (see FIG. 1). The number of the connection lines 20 that connect two device mounting portions 100R may vary according to a type of the device 100 (see FIG. 1) mounted on each device mounting portion 100R. Also, although each or one of both sides of the connection line 20 formed on the bending region BR is connected to one device mounting portion 100R, the example embodiment is not limited thereto and the connection line 20 formed on the bending region BR may be designed to extend and be connected to the mounting region DR in various ways.

When the connection line 20 is connected to the device mounting portion 100R, the connection line 20 extends into the device mounting portion 100R in order to be electrically connected to the device 100 mounted on the device mounting portion 100R. Accordingly, an arrangement and a shape of the connection line 20 in the device mounting portion 100R may vary according to the device 100 mounted on the device mounting portion 100R, and thus the arrangement and the shape of the connection line 20 in the device mounting portion 100R are not shown.

Although the connection line 20 may be formed on a top surface, a bottom surface, or both the top surface and the bottom surface of the base substrate 12, the example embodiment is not limited thereto and the connection line 20 may be formed in the base substrate 12.

The base substrate 12 may include an opening 30a formed in the bending region BR. The opening 30a may be formed adjacent to each or at least one of both edges 12E of the bending region BR. For example, the opening 30a may be formed to contact each or at least one of both edges 12E of the bending region BR. The openings 30a adjacent to both edges 12E of the bending region BR may face each other. The openings 30a adjacent to both edges 12E of the bending region BR may be substantially symmetric about a central line between both edges 12E of the bending region BR. The opening 30a may be located on a virtual bending central line BC that connects both edges 12E of the bending region BR.

The virtual bending central line BC refers to a virtual line that connects portions of the bending region BR on which the largest deformation, that is, the largest compression and/or tension, of the PCB 10a occurs when the electronic apparatus 1 (see FIG. 1) including the PCB 10a is repeatedly bent during use.

The opening 30a may be recessed from each or at least one of both edges 12E of the base substrate 12, that is, from each or at least one of both edges 12E of the bending region BR. A boundary of the opening 30a may have an arc shape. The boundary of the opening 30a may have, for example, an arc shape with an angle of about 180° or less. When the boundary of the opening 30a has an arc shape, it means that the boundary of the opening 30a on the top surface or the bottom surface of the base substrate 12 has an arc shape. That is, the boundary of the opening 30a may have an arc shape on a side surface of the base substrate 12.

A guard pattern 32a may be formed along the boundary of the opening 30a on the top surface and/or the bottom surface of the base substrate 12. The guard pattern 32a may have a substantially constant width along the boundary of the opening 30a.

The guard pattern 32a may be formed of or include a material that is different from the material of the base substrate 12. The guard pattern 32a may be formed of or include, but is not limited to, the same material as the material of the connection line 20. The guard pattern 32a may be formed of or include, for example, an ED copper foil, an RA copper foil, a stainless steel foil, an aluminum foil, an ultra-thin copper foil, sputtered copper, or a copper alloy.

When an electronic apparatus 1 including a PCB is repeatedly bent, cracks may occur on a portion of the PCB on which stress caused by fatigue is concentrated. Also, the cracks may propagate into a base substrate to short a connection line, thereby reducing the reliability of the electronic apparatus.

However, in the PCB 10a according to the example embodiment, since the opening 30a is formed along each or at least one of both edge 12E on the virtual bending central line BC on which stress caused by fatigue is concentrated, stress may be distributed to the boundary of the opening 30a, thereby substantially preventing cracks from occurring. Accordingly, the connection line 20 may be substantially prevented from being shorted, thereby improving the reliability of the electronic apparatus 1 including the PCB 10a.

Also, since the guard pattern 32a that is formed of or include a material that is different from the material of the base substrate 12 is formed on the top surface and/or the bottom surface of the base substrate 12 along the boundary of the opening 30a, even when cracks occur on a portion of the base substrate 12, the cracks may be substantially prevented from propagating due to the guard pattern 32a, thereby substantially preventing the connection line 20 from being shorted.

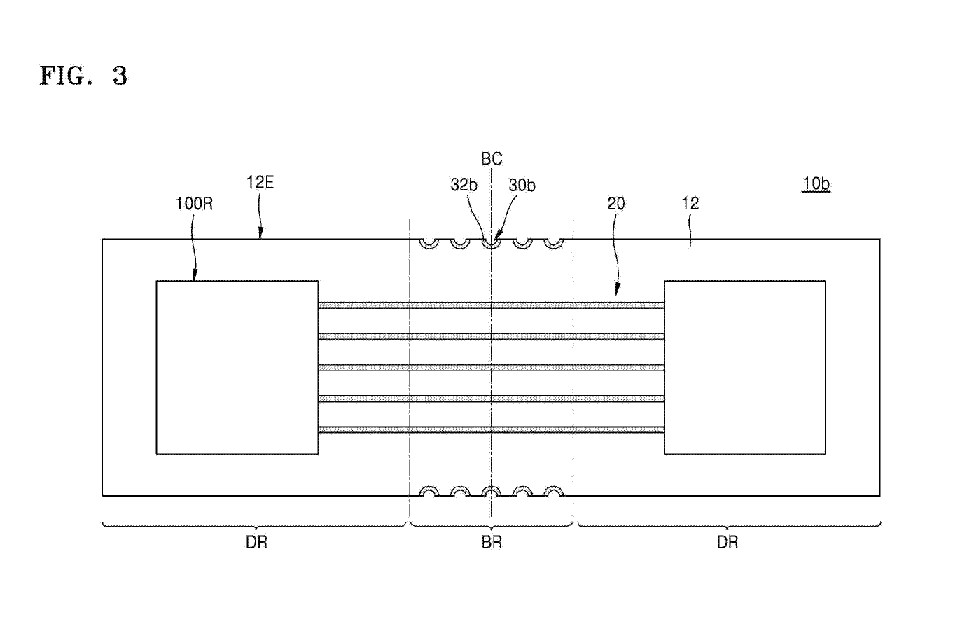

FIG. 3 is a plan view illustrating essential parts of a PCB 10b according to an example embodiment.

Referring to FIG. 3, the PCB 10b includes the base substrate 12 and the connection line 20 formed on the base substrate 12. The base substrate 12 included in the PCB 10b may include the bending region BR having both edges 12E and the mounting regions DR extending from both ends of the bending region BR.

The base substrate 12 may include an opening 30b formed in the bending region BR. The opening 30b may be formed adjacent to each or at least one of both edges 12E of the bending region BR. For example, the opening 30b may be formed to contact each or at least one of both edges 12E of the bending region BR. A plurality of the openings 30b may be arranged to form a line along each or at least one of both edges 12E of the bending region BR. Widths of the plurality of openings 30b arranged to form the line along each or at least one of both edges 12E of the bending region BR may be substantially constant.

The plurality of openings 30b adjacent to both edges 12E of the bending region BR may face each other. The openings 30b adjacent to both edges 12E of the bending region BR may be substantially symmetric about a central line between both edges 12E of the bending region BR. One of the plurality of openings 30b arranged to form the line along each or at least one of both edges 12E of the bending region BR may be located on the virtual bending central line BC that connects both edges 12E of the bending region BR.

The opening 30b may be recessed from each or at least one of both edges 12E of the base substrate, that is, each or at least one of both edges 12E of the bending region BR. A boundary of the opening 30b may have an arc shape. The boundary of the opening 30b may have, for example, an arc shape with an angle of about 180° or less. That is, the boundary of the opening 30b may have an arc shape on a side surface of the base substrate 12.

A guard pattern 32b may be formed along the boundary of the opening 30b on a top surface and/or a bottom surface of the base substrate 12. The guard pattern 32b may have a substantially constant width along the boundary of the opening 30b.

In the PCB 10b according to the example embodiment, since the plurality of openings 30b are formed along each or at least one of both edges 12E of the bending region BR to which stress caused by fatigue is applied, the stress may be distributed to the boundaries of the plurality of openings 30b, thereby substantially preventing cracks from occurring. Accordingly, the connection line 20 may be substantially prevented from being shorted, thereby improving the reliability of the electronic apparatus 1 including the PCB 10b.

Also, since the guard pattern 32b that is formed of or include a material that is different from the material of the base substrate 12 is formed on the top surface and/or the bottom surface of the base substrate 12 along the boundary of the opening 30b, even when cracks occur on a portion of the base substrate 12, the cracks may be substantially prevented from propagating due to the guard pattern 32b, thereby substantially preventing the connection line 20 from being shorted.

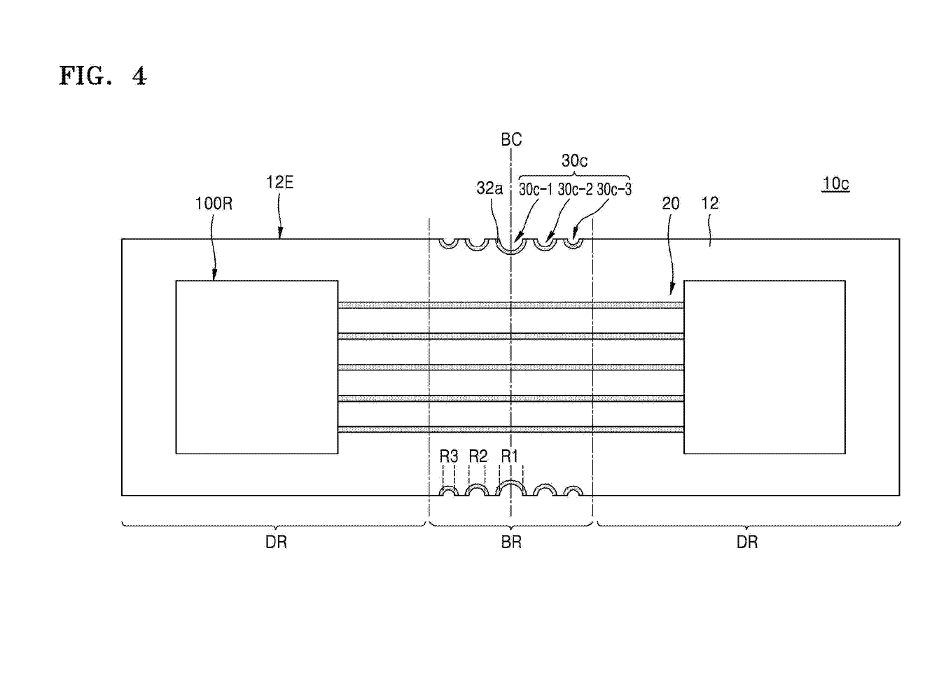

FIG. 4 is a plan view illustrating essential parts of a PCB 10c according to an example embodiment.

Referring to FIG. 4, the PCB 10c includes the base substrate 12 and the connection line 20 formed on the base substrate 12. The base substrate 12 included in the PCB 10b may include the bending region BR having both edges 12E and the mounting regions DR extending from both ends of the bending region BR.

The base substrate 12 may include an opening 30c formed in the bending region BR. The opening 30c may be formed adjacent to each or at least one of both edges 12E of the bending region BR. For example, the opening 30c may be formed to contact each or at least one of both edges 12E of the bending region BR.

A plurality of the openings 30c may be arranged to form a line along each or at least one of both edges 12E of the bending region BR. The plurality of openings 30c adjacent to both edges 12E of the bending region BR may face each other. The openings 30c adjacent to both edges 12E of the bending region BR may be substantially symmetric about a central line between both edges 12E of the bending region BR. One of the plurality of openings 30c arranged to form the line along each or at least one of both edges 12E of the bending region BR may be located on the virtual bending central line BC that connects both edges 12E of the bending region BR.

Widths of the plurality of openings 30c arranged to form the line along each or at least one of both edges 12E of the bending region BR may not be constant. For example, widths R3 of openings 30c-3 formed on both ends of the line may be less than widths R1 and R2 of openings 30c-1 and 30c-2 formed in the line from among the plurality of openings 30c arranged to form the line along each or at least one of both edges 12E of the bending region BR. For example, the width R1 of the opening 30c-1 located on the virtual bending central line BC is the largest and the widths R3 of the openings 30c-3 formed on both ends of the line may be the smallest from among the plurality of openings 30c arranged to form the line along each or at least one of both edges 12E of the bending region BR. For example, widths of the plurality of openings 30c arranged to form the line along each or at least one of both edges 12E of the bending region BR may decrease towards both ends of the line from the center of the virtual bending central line BC.

The opening 30c may be recessed from each or at least one of both edges 12E of the base substrate 12, that is, from each or at least one of both edges 12E of the bending region BR. A boundary of the opening 30c may have an arc shape. The boundary of the opening 30c may have, for example, an arc shape with an angle of about 180° or less. That is, the boundary of the opening 30c may have an arc shape on a side surface of the base substrate 12.

A guard pattern 32c may be formed along the boundary of the opening 30c on a top surface and/or a bottom surface of the base substrate 12. The guard pattern 32c may have a substantially constant width along the boundary of the opening 30c.

In the PCB 10c according to the example embodiment, since the plurality of openings 30c are formed along each or at least one of both edges 12E of the bending region BR to which stress caused by fatigue is applied, in particular, the opening 30c-1 having a largest width is formed along each or at least one of both edges 12E on the virtual bending central line BC on which stress caused by fatigue is concentrated, the stress may be distributed to the boundaries of the plurality of openings 30c, thereby substantially preventing cracks from occurring. Accordingly, the connection line 20 may be substantially prevented from being shorted, thereby improving the reliability of the electronic apparatus 1 including the PCB 10c.

Also, since the guard pattern 32c that is formed of or include a material that is different from the material of the base substrate 12 is formed on the top surface and/or the bottom surface of the base substrate 12 along the boundary of the opening 30c, even when cracks occur on a portion of the base substrate 12, the cracks may be substantially prevented from propagating due to the guard pattern 32c, thereby substantially preventing the connection line 20 from being shorted.

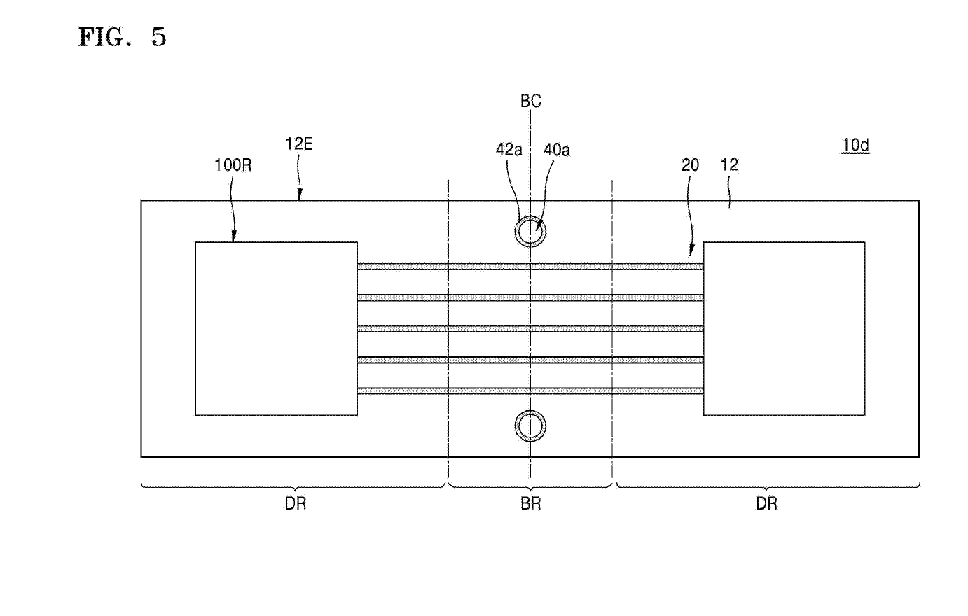

FIG. 5 is a plan view illustrating essential parts of a PCB 10d according to an example embodiment.

Referring to FIG. 5, the PCB 10d includes the base substrate 12 and the connection line 20 formed on the base substrate 12. The base substrate 12 included in the PCB 10d may include the bending region BR having both edges 12E and the mounting regions DR extending from both ends of the bending region BR.

The base substrate 12 may include an opening 40a formed in the bending region BR. The opening 40a may be formed adjacent to each or at least one of both edges 12E of the bending region BR. For example, the opening 40a may be spaced apart from each or at least one of both edges 12E of the bending region BR and may be located adjacent to the edge 12E. The opening 40a may be formed between the connection line 20 and each or at least one of both edges 12E of the bending region BR.

A plurality of the openings 40a adjacent to both edges 12E of the bending region BR may face each other. The openings 40a adjacent to both edges 12E of the bending region BR may be substantially symmetric about a central line between both edges 12E of the bending region BR. The openings 40a may be located on the virtual bending central line BC that connects both edges 12E of the bending region BR.

The opening 40a may be a through-hole that is formed in the base substrate 12 and extends from a top surface of the base substrate 12 to a bottom surface of the base substrate 12. A boundary of the opening 40a may have a circular shape. When the boundary of the opening 40a has a circular shape, it means that the boundary of the opening 40a on the top surface or the bottom surface of the base substrate 12 has a circular shape.

A guard pattern 42a may be formed along the boundary of the opening 40a on the top surface and/or the bottom surface of the base substrate 12. The guard pattern 42a may have a substantially constant width along the boundary of the opening 40a.

In the PCB 10d according to the example embodiment, the opening 40a is formed between the connection line 20 and each or at least one of both edges 12E on the virtual bending central line BC on which stress caused by fatigue is concentrated. Accordingly, even when cracks occur on the edge 12E on the virtual bending central line BC on which stress caused by fatigue is concentrated, the cracks may meet the opening 40a and thus may be substantially prevented from further propagating into the base substrate 12. Accordingly, the connection line 20 may be substantially prevented from being shorted, thereby improving the reliability of the electronic apparatus 1 including the PCB 10d.

Also, since the guard pattern 42a that is formed of or include a material that is different from the material of the base substrate 12 is formed on the top surface and/or the bottom surface of the base substrate 12 along the boundary of the opening 40a, even when cracks occur on a portion of the base substrate 12 that contacts the boundary of the opening 40a, the cracks may be substantially prevented from propagating due to the guard pattern 42a, thereby substantially preventing the connection line 20 from being shorted.

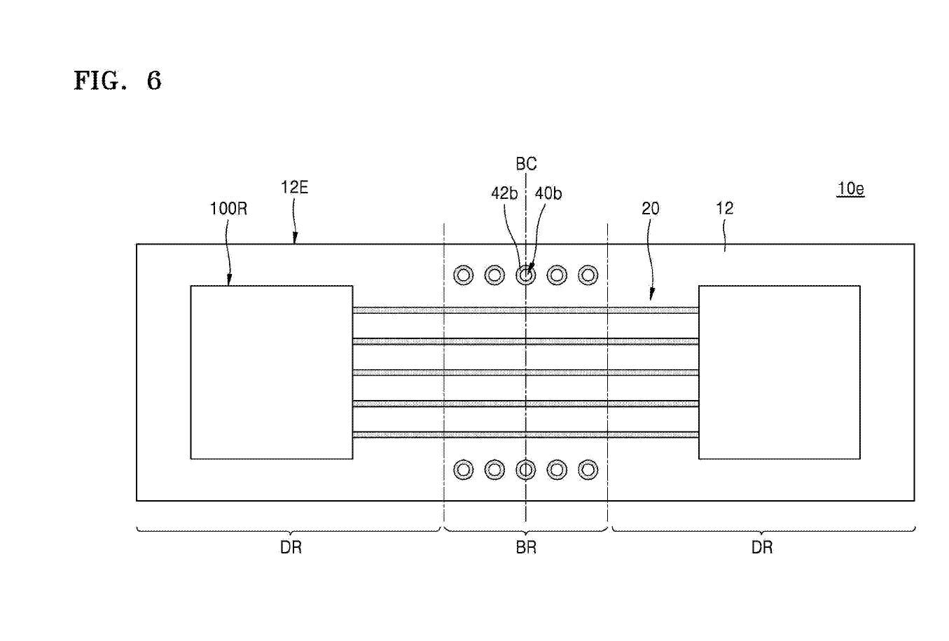

FIG. 6 is a plan view illustrating essential parts of a PCB 10e according to an example embodiment.

Referring to FIG. 6, the PCB 10e includes the base substrate 12 and the connection line 20 formed on the base substrate 12. The base substrate 12 included in the CPB 10e may include the bending region BR having both edges 12E and the mounting regions DR extending from both ends of the bending region BR.

The base substrate 12 may include an opening 40b formed in the bending region BR. The opening 40b may be formed adjacent to each or at least one of both edges 12E of the bending region BR. For example, the opening 40b may be spaced apart from each or at least one of both edges 12E of the bending region BR and may be located adjacent to the edge 12E. The opening 40b may be formed between the connection line 20 and each or at least one of both edges 12E of the bending region BR. A plurality of the openings 40b may be arranged to form a line along each or at least one of both edges 12E of the bending region BR. Widths of the openings 40b arranged to form the line along each or at least one of both edges 12E of the bending region BR may be substantially constant.

The plurality of openings 40b adjacent to both edges 12E of the bending region BR may face each other. The openings 40b adjacent to both edges 12E of the bending region BR may be substantially symmetric about a central line between both edges 12E of the bending region BR. One of the plurality of openings 40b arranged to form the line along each or at least one of both edges 12E of the bending region BR may be located on the virtual bending central line BC that connects both edges 12E of the bending region BR.

The opening 40b may be a through-hole that is formed in the base substrate 12 and extends from a top surface of the base substrate 12 to a bottom surface of the base substrate 12. A boundary of the opening 40b may have a circular shape.

A guard pattern 42b may be formed along the boundary of the opening 40b on the top surface and/or the bottom surface of the base substrate 12. The guard pattern 42b may have a substantially constant width along the boundary of the opening 40b.

In the PCB 10e according to the example embodiment, a plurality of the openings 40b are formed between the connection line 20 and each or at least one of both edges 12E of the bending region BR to which stress caused by fatigue is applied. Accordingly, even when cracks occur on the edge 12E of the bending region BR due to the stress caused by fatigue, the cracks may meet the openings 40b and thus may be substantially prevented from further propagating into the base substrate 12. Accordingly, the connection line 20 may be substantially prevented from being shorted, thereby improving the reliability of the electronic apparatus 1 including the PCB 10e.

Also, since the guard pattern 42b that is formed of or include a material that is different from the material of the base substrate 12 is formed on the top surface and/or the bottom surface of the base substrate 12 along the boundary of the opening 40b, even when cracks occur on a portion of the base substrate 12 that contacts the boundary of the opening 40a, the cracks may be substantially prevented from propagating due to the guard pattern 42a, thereby substantially preventing the connection line 20 from being shorted.

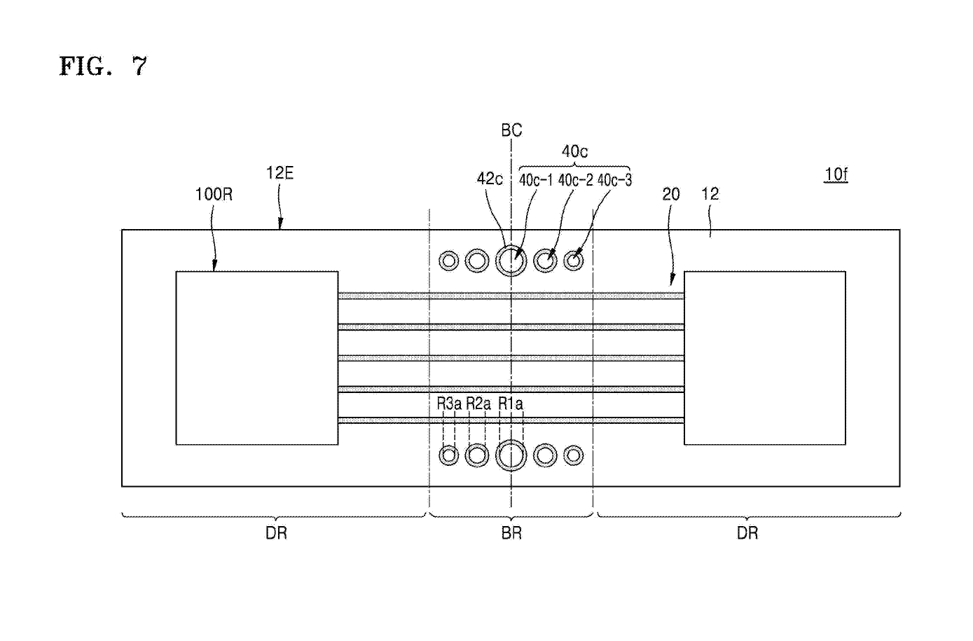

FIG. 7 is a plan view illustrating essential parts of a PCB 10f according to an example embodiment.

Referring to FIG. 7, the PCB 10f includes the base substrate 12 and the connection line 20 formed on the base substrate 12. The base substrate 12 included in the PCB 10f may include the bending region BR having both edges 12E and the mounting regions DR extending from both ends of the bending region BR.

The base substrate 12 may include an opening 40c formed in the bending region BR. The opening 40c may be formed adjacent to each or at least one of both edges 12E of the bending region BR. For example, the opening 40c may be spaced apart from each or at least one of both edges 12E of the bending region BR and may be located adjacent to the edge 12E. The opening 40c may be formed between the connection line 20 and each or at least one of both edges 12E of the bending region BR.

A plurality of the openings 40c may be arranged to form a line along each or at least one of both edges 12E of the bending region BR. The plurality of openings 40c adjacent to both edges 12E of the bending region BR may face each other. The openings 40c adjacent to both edges 12E of the bending region BR may be substantially symmetric about a central line between both edges 12E of the bending region BR. One of the plurality of openings 40c arranged to form the line along each or at least one of both edges 12E of the bending region BR may be located on the virtual bending central line BC that connects both edges 12E of the bending region BR.

Widths of the plurality of openings 40c arranged to form the line along each or at least one of both edges 12E of the bending region BR may not be constant. For example, widths R3a of openings 40c-3 formed on both ends of the line may be less than widths R1a and R2a of openings 40c-1 and 40c-2 formed in the line from among the plurality of openings 40c arranged to form the line along each or at least one of both edges 12E of the bending region BR. For example, the width R1a of the opening 40c-1 located on the virtual bending central line BC may be the largest and the widths R3a of the openings 40c-3 formed on both ends of the line may be the smallest from among the plurality of openings 40c arranged to form the line along each or at least one of both edges 12E of the bending region BR. For example, widths of the plurality of openings 40c arranged to form the line along each or at least one of both edges 12E of the bending region BR may decrease toward both ends of the line from the center of the virtual bending central line BC.

The opening 40c may be a through-hole that is formed in the base substrate 12 and extends from a top surface of the base substrate 12 to a bottom surface of the base substrate 12. A boundary of the opening 40c may have a circular shape.

A guard pattern 42c may be formed along the boundary of the opening 40c on the top surface and/or the bottom surface of the base substrate 12. The guard pattern 42c may have a substantially constant width along the boundary of the opening 40c.

In the PCB 10f according to the example embodiment, a plurality of the openings 40c are formed along each or at least one of both edges 12E of the bending region BR to which stress caused by fatigue is applied, and in particular, the opening 40c-1 having the largest width is formed between the connection line 20 and each or at least one of edges 12E on the virtual bending central line BC on which the stress caused by fatigue is concentrated. Accordingly, even when cracks occur on the edge 12E of the bending region BR due to the stress caused by fatigue, the cracks may meet the openings 40c and thus may be substantially prevented from further propagating into the base substrate 12. Accordingly, the connection line 20 may be substantially prevented from being shorted, thereby improving the reliability of the electronic apparatus 1 including the PCB 10f.

Also, since the guard pattern 42c that is formed of or include a material that is different from the material of the base substrate 12 formed on the top surface and/or the bottom surface of the base substrate 12 along the boundary of the opening 40c, even when cracks occur on a portion of the base substrate 12, the cracks may be substantially prevented from propagating due to the guard pattern 42c, thereby substantially preventing the connection line 20 from being shorted.

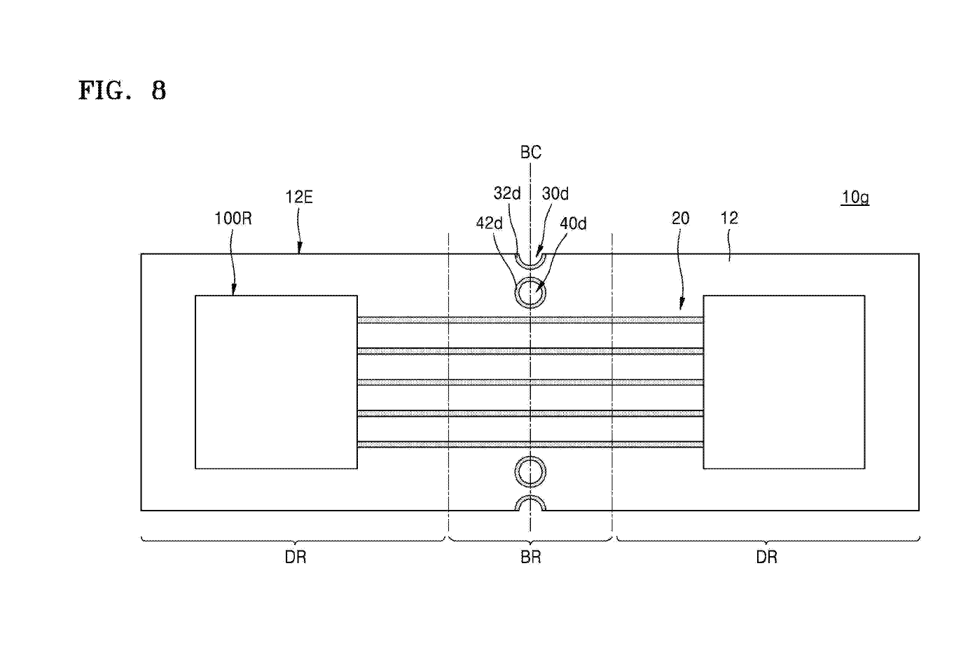

FIG. 8 is a plan view illustrating essential parts of a PCB 10g according to an example embodiment.

Referring to FIG. 8, the PCB 10g includes the base substrate 12 and the connection line 20 formed on the base substrate 12. The base substrate 12 included in the PCB 12g may include the bending region BR having both edges 12E and the mounting regions DR extending from both ends of the bending region BR.

The base substrate 12 may include openings formed in the bending region BR. The openings may be formed adjacent to both edges 12E of the bending region BR. The openings adjacent to both edges 12E of the bending region BR may face each other. The openings adjacent to both edges 12E of the bending region BR may be substantially symmetric about a central line between both edges 12E of the bending region BR. The openings may be located on the virtual bending central line BC that connects both edges 12E of the bending region BR.

The openings may include a first opening 30d and a second opening 40d. The first opening 30d may be similar to or the same as the opening 30a of FIG. 2 and the second opening 40d may be similar to or the same as the opening 40a of FIG. 5.

For example, the first opening 30d may be formed to contact each or at least one of both edges 12E of the bending region BR. The first opening 30d may be recessed from each or at least one of both edges 12E of the base substrate 12, that is, from each or at least one of both edges 12E of the bending region BR. A boundary of the first opening 30d may have an arc shape. The boundary of the first opening 30d may have, for example, an arc shape with an angle of about 180° or less. The boundary of the first opening 30d may have an arc shape on a side surface of the base substrate 12.

For example, the second opening 40d may be spaced apart from each or one of both edges 12E of the bending region BR and may be located adjacent to the edge 12E. The second opening 40d may be spaced apart from the first opening 30d to be adjacent to the first opening 30d and may be formed in the base substrate 12. The second opening 40d may be formed between the connection line 20 and the first opening 30d. The second opening 40d may be a through-hole that is formed in the base substrate 12 and extends from a top surface of the base substrate 12 to a bottom surface of the base substrate 12. A boundary of the second opening 40d may have a circular shape.

First and second guard patterns 32d and 42d may be respectively formed along the boundaries of the first and second openings 30d and 40d on the top surface and/or the bottom surface of the base substrate 12. The first and second guard patterns 32d and 42d may have substantially constant widths along the boundaries of the first and second openings 30d and 40d. The first guard pattern 32d formed along the boundary of the first opening 30d and the second guard pattern 42d formed along the boundary of the second opening 40d may be spaced apart from each other.

In the PCB 10g according to the example embodiment, cracks may be substantially prevented from occurring on the edge 12E of the bending region BR due to the first opening 30d. Even when cracks occur on the edge 12E of the bending region BR and propagate into the base substrate 12, the cracks may meet the second opening 40d and thus may be substantially prevented from further propagating into the base substrate 12. Accordingly, the connection line 20 may be substantially prevented from being shorted, thereby improving the reliability of the electronic apparatus 1 including the PCB 10g.

Also, since the first and second guard patterns 32d and 42d that are formed of or include materials different from the material of the base substrate 12 are formed on the top surface and/or the bottom surface of the base substrate 12 respectively along the boundaries of the first and second openings 30d and 40d, cracks may be substantially prevented from occurring and propagating due to the first and second guard patterns 32d and 42d, thereby substantially preventing the connection line 20 from being shorted.

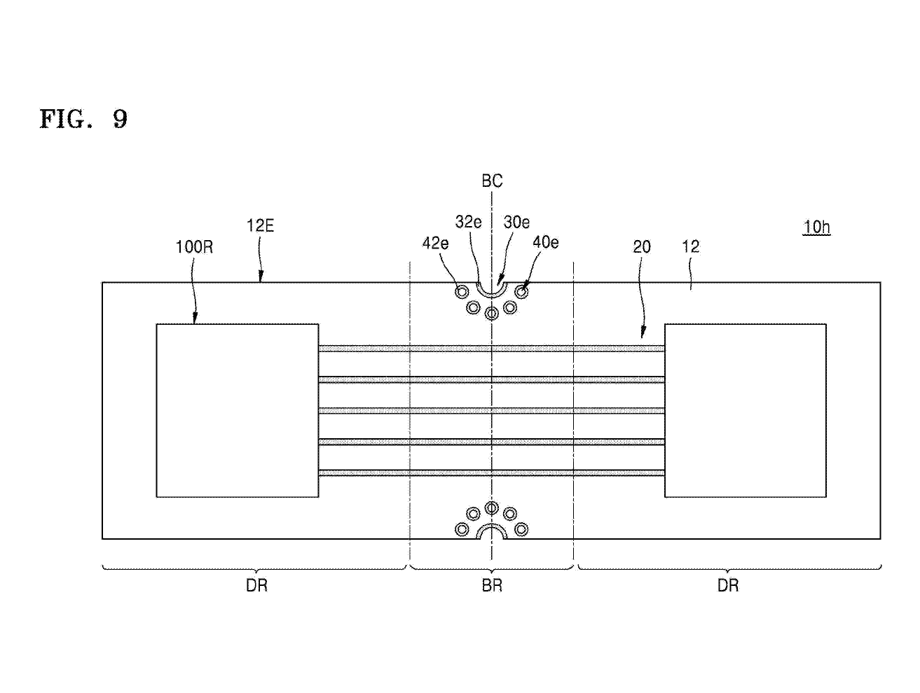

FIG. 9 is a plan view illustrating essential parts of a PCB 10h according to an example embodiment.

Referring to FIG. 9, the PCB 10h includes the base substrate 12 and the connection line 20 formed on the base substrate 12. The base substrate 12 included in the PCB 10h may include the bending region BR having both edges 12E and the mounting regions DR extending from both ends of the bending region BR.

The base substrate 12 may include openings formed in the bending region BR. The openings may be formed adjacent to both edges 12E of the bending region BR. The openings adjacent to both edges 12E of the bending region BR may face each other. The openings adjacent to both edges 12E of the bending region BR may be substantially symmetric about a central line between both edges 12E of the bending region BR.

The openings may include a first opening 30e and a second opening 40e. The first opening 30e may be similar to or the same as the opening 30a of FIG. 2.

For example, the first opening 30e may be formed to contact each or at least one of both edges 12E of the bending region BR. The first opening 30e may be located on the virtual bending central line BC that connects both edges 12E of the bending region BR. The first opening 30e may be recessed from each or at least one of both edges 12E of the base substrate 122, that is, from each or at least one of both edges 12E of the bending region BR. A boundary of the first opening 30e may have an arc shape. For example, the boundary of the first opening 30e may have an arc shape with an angle of about 180° or less. The boundary of the first opening 30e may have an arc shape on a side surface of the base substrate 12.

The second opening 40e may be spaced apart from the first opening 30e to be adjacent to the first opening 30e and may be formed in the base substrate 12. The second opening 40e may be formed between the connection line 20 and the first opening 30e. The second opening 40e may be a through-hole that is formed in the base substrate 12 and extends form a top surface of the base substrate 12 to a bottom surface of the base substrate 12. A boundary of the second opening 40e may have a circular shape. A plurality of the second openings 40e may be formed along the boundary of the first opening 30e. A width of each or at least one of the plurality of second openings 40e may be less than a width of the first opening 30e. Each or at least one of the plurality of second openings 40e may be spaced by a desired, or alternatively predetermined distance from the boundary of the first opening 30e.

First and second guard patterns 32e and 42e may be respectively formed along the boundaries of the first and second openings 30e and 40e on the top surface and/or the bottom surface of the base substrate 12. The first and second guard patterns 32e and 42e may have substantially constant widths along the boundaries of the first and second openings 30e and 40e. The first guard pattern 32e formed along the boundary of the first opening 30e and the second guard pattern 42e formed along the boundary of the second opening 40e may be spaced apart from each other.

In the PCB 10h according to the example embodiment, cracks may be substantially prevented from occurring on the edge 12E of the bending region BR due to the first opening 30e. Even when cracks occur on the edge 12E of the bending region BR and propagate into the base substrate 12 or the first opening 30e fails to substantially prevent cracks from occurring, the cracks may meet the plurality of second openings 40e surrounding the boundary of the first opening 30e and thus may be substantially prevented from further propagating into the base substrate 12. Accordingly, the connection line 20 may be substantially prevented from being shorted, thereby improving the reliability of the electronic apparatus 1 including the PCB 10h.

Also, since the first and second guard patterns 32e and 42e that are formed of or include materials different from the material of the base substrate 12 are formed on the top surface and/or the bottom surface of the base substrate 122 respectively along the boundaries of the first and second openings 30e and 40e, cracks may be substantially prevented from occurring and propagating due to the first and second guard patterns 32e and 42e, thereby substantially preventing the connection line 20 from being shorted.

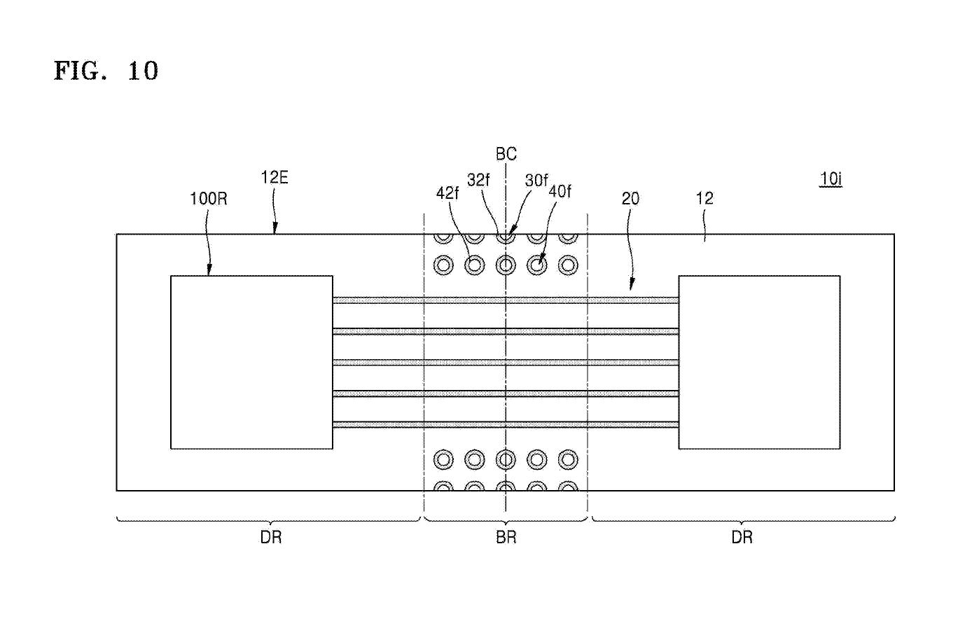

FIG. 10 is a plan view illustrating essential parts of a PCB 10i according to an example embodiment.

Referring to FIG. 10, the PCB 10i includes the base substrate 12 and the connection line 20 formed on the base substrate 12. The base substrate 12 included in the PCB 10i may include the bending region BR having both edges 12E and the mounting regions DR extending from both ends of the bending region BR.

The base substrate 12 may include openings formed in the bending region BR. The openings may be formed adjacent to both edges 12E of the bending region BR. The openings adjacent to both edges 12E of the bending region BR may face each other. The openings adjacent to both edges 12E of the bending region BR may be substantially symmetric about a central line between both edges 12E of the bending region BR.

The openings may include a first opening 30f and a second opening 40f. The first opening 30f may be similar to or the same as the opening 30b of FIG. 3 and the second opening 40f may be similar to or the same as the opening 40b of FIG. 6.

A plurality of the first openings 30f may be arranged to form a line along each or at least one of both edges 12E of the bending region BR. Widths of the plurality of first openings 30f arranged to form the line along each or at least one of both edges 12E of the bending region BR may be substantially constant. A plurality of the second openings 40f may be arranged to form a line along each or at least one of both edges 12E of the bending region BR. Widths of the plurality of second openings 40f arranged to form the line along each or at least one of both edges 12E of the bending region BR may be substantially constant. Widths of the first openings 30f may be substantially equal to or less than widths of the second openings 40f.

One of the plurality of first openings 30f arranged to form the line along each or at least one of both edges 12E of the bending region BR may be located on the virtual bending central line BC that connects both edges 12E of the bending region BR. One of the plurality of second openings 40f arranged to form the line along each or at least one of both edges 12E of the bending region BR may be located on the virtual bending central line BC that connects both edges 12E of the bending region BR.

For example, the first opening 30f may be formed to contact each or at least one of both edges 12E of the bending region BR. The first opening 30f may be recessed from each or at least one of both edges 12E of the base substrate 12, that is, from each or at least one of both edges 12E of the bending region BR. A boundary of the first opening 30f may have an arc shape. The boundary of the first opening 30f may have an arc shape with an angle of about 180° or less. The boundary of the first opening 30f may have an arc shape on a side surface of the base substrate 12.

For example, the second opening 40f may be spaced apart from each or at least one of both edges 12E of the bending region BR and may be located adjacent to the edge 12E. The second opening 40f may be spaced apart from the first opening 30f to be adjacent to the first opening 30f and may be formed in the base substrate 12. The second opening 40f may be formed between the connection line 20 and the first opening 30f. The second opening 40f may be a through-hole that is formed in the base substrate 12 and extends from a top surface of the base substrate 12 to a bottom surface of the base substrate 12. A boundary of the second opening 40f may have a circular shape.

First and second guard patterns 32f and 42f may be respectively formed along the boundaries of the first and second openings 30f and 40f on the top surface and/or the bottom surface of the base substrate 12. The first and second guard patterns 32f and 42f may have substantially constant widths along the boundaries of the first and second openings 30f and 40f. The first guard pattern 32f formed along the boundary of the first opening 30f and the second guard pattern 42f formed along the boundary of the second opening 40f may be spaced apart from each other.

In the PCB 10i according to the example embodiment, cracks may be substantially prevented from occurring on the edge 12E of the bending region BR. Even when cracks occur on the edge 12E of the bending region BR and propagate into the base substrate 12, the cracks may meet the second opening 40f and thus may be substantially prevented from further propagating into the base substrate 12. Accordingly, the connection line 20 may be substantially prevented from being shorted, thereby improving the reliability of the electronic apparatus 1 including the PCB 10i.

Also, since the first and second guard patterns 32f and 421f that are formed of or include materials different from the material of the base substrate 12 are formed on the top surface and/or the bottom surface of the base substrate 12 respectively along the boundaries of the first and second openings 30f and 40f, cracks may be substantially prevented from occurring and propagating due to the first and second guard patterns 32f and 42f, thereby substantially preventing the connection line 20 from being shorted.

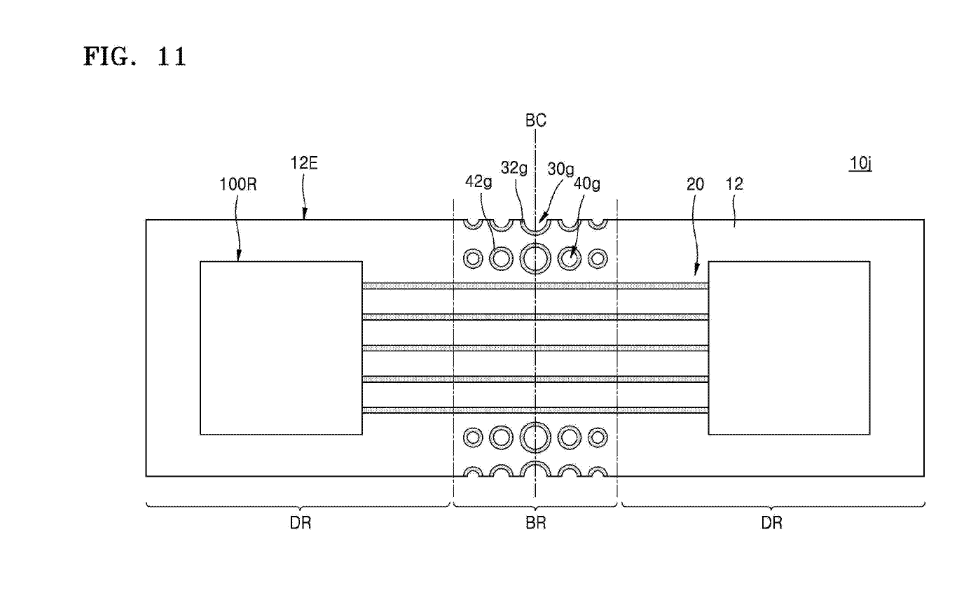

FIG. 11 is a plan view illustrating essential parts of a PCB 10j according to an example embodiment.

Referring to FIG. 11, the PCB 10j includes the base substrate 12 and the connection line 20 formed on the base substrate 12. The base substrate 12 included in the PCB 10j may include the bending region BR having both edges 12E and the mounting regions DR extending from both ends of the bending region BR.

The base substrate 12 may include openings formed in the bending region BR. The openings may include a first opening 30g and a second opening 40g. The PCB 10j is similar to or the same as the PCB 10i of FIG. 10 except that the first opening 30g is similar to or the same as the opening 30c of FIG. 4 and the second opening 40g is similar to or the same as the opening 40c of FIG. 7, and thus a detailed explanation thereof will not be given. That is, from among a plurality of the first openings 30g, a width of the first opening 30g located on the virtual bending central line BC is the largest, and from among a plurality of the second openings 40g, a width of the second opening 40g located on the virtual bending central line BC is the largest.

In the PCB 10j according to the example embodiment, cracks may be substantially prevented from occurring on the edge 12E of the bending region BR due to the first opening 30g. Even when cracks occur on the edge 12E of the bending region BR and propagate into the base substrate 12, the cracks may meet the second opening 40g and thus may be substantially prevented from further propagating into the base substrate 12. Accordingly, the connection line 20 may be substantially prevented from being shorted, thereby improving the reliability of the electronic apparatus 1 including the PCB 10j.

Also, since first and second guard patterns 32g and 42g that are formed of or include materials different from the material of the base substrate 12 are formed on a top surface and/or a bottom surface of the base substrate 122 respectively along boundaries of the first and second openings 30g and 40g, cracks may be substantially prevented from occurring and propagating due to the first and second guard patterns 32g and 42g, thereby substantially preventing the connection line 20 from being shorted.

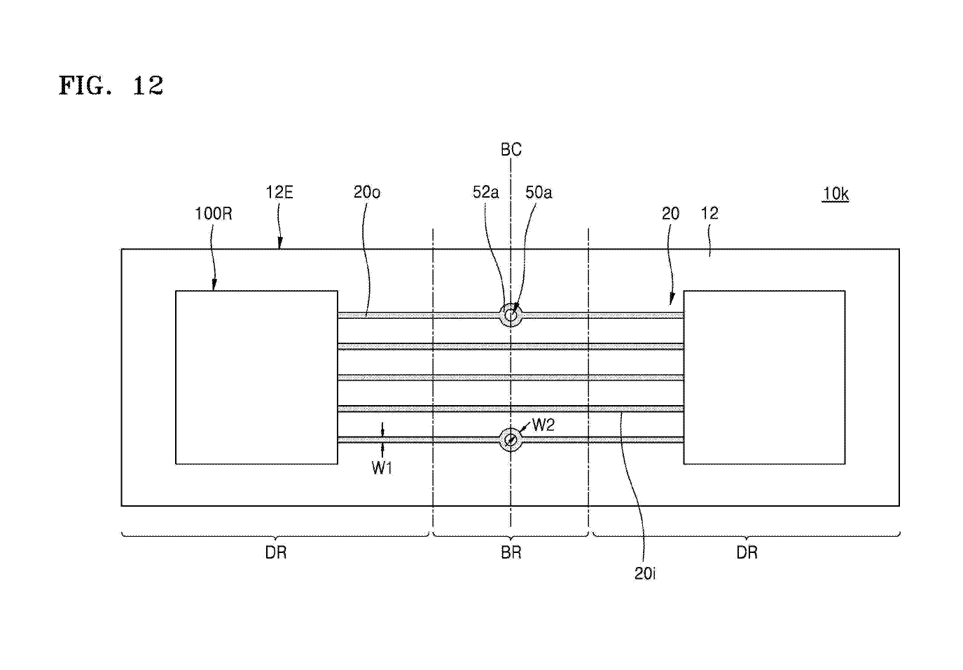

FIG. 12 is a plan view illustrating essential parts of a PCB 10k according to an example embodiment.

Referring to FIG. 12, the PCB 10k includes the base substrate 12 and the connection line 20 formed on the base substrate 12. The base substrate 12 included in the PCB 10k may include the bending region BR having both edges 12E and the mounting regions DR extending from both ends of the bending region BR.

The base substrate 12 may include an opening 50a formed in the bending region BR. The opening 50a may be formed in the connection line 20. The opening 50a may be formed in an outer connection line 20o that is the closest to each or at least one of both edges 12E of the bending region BR from among a plurality of the connection lines 20. The opening 50a may not be formed in inner connection lines 20i other than the outer connection line 20o. The opening 50a may be located on the virtual bending central line BC that connects both edges 12E of the bending region BR.

The opening 50a may be a through-hole that is formed in the base substrate 12 and extends from a top surface of the base substrate 12 to a bottom surface of the base substrate 12. A boundary of the opening 50a may have a circular shape.

A guard pattern 52a may be formed along the boundary of the opening 50a on the top surface and/or the bottom surface of the base substrate 12. The guard pattern 52a may have a substantially constant width along the boundary of the opening 50a. The guard pattern 52a may serve as a part of the outer connection line 20o. That is, the outer connection line 20o and the guard pattern 52a may be integrally formed with each other. A width W1 of the outer connection line 20o and a width W2 of the guard pattern 52a may be substantially equal to each other.

In the PCB 10k according to the example embodiment, the opening 50a is formed in the connection line 20, in particular, in the outer connection line 20o, on the virtual bending central line BC on which stress caused by fatigue is concentrated. Accordingly, even when cracks occur on the edge 12E on the virtual bending central line BC on which stress caused by fatigue is concentrated and propagate, the cracks may meet the opening 50a and thus may be substantially prevented from further propagating into the base substrate 12. Accordingly, even when the cracks propagate to a portion of the guard pattern 52a formed on the outer connection line 20o, that is, to a portion of the guard pattern 52a that is adjacent to the edge 12E from the opening 50a, the outer connection line 20o may be substantially prevented from being shorted due to a portion of the guard pattern 52a that is far from the edge 12E, thereby improving the reliability of the electronic apparatus 1 including the PCB 10k.

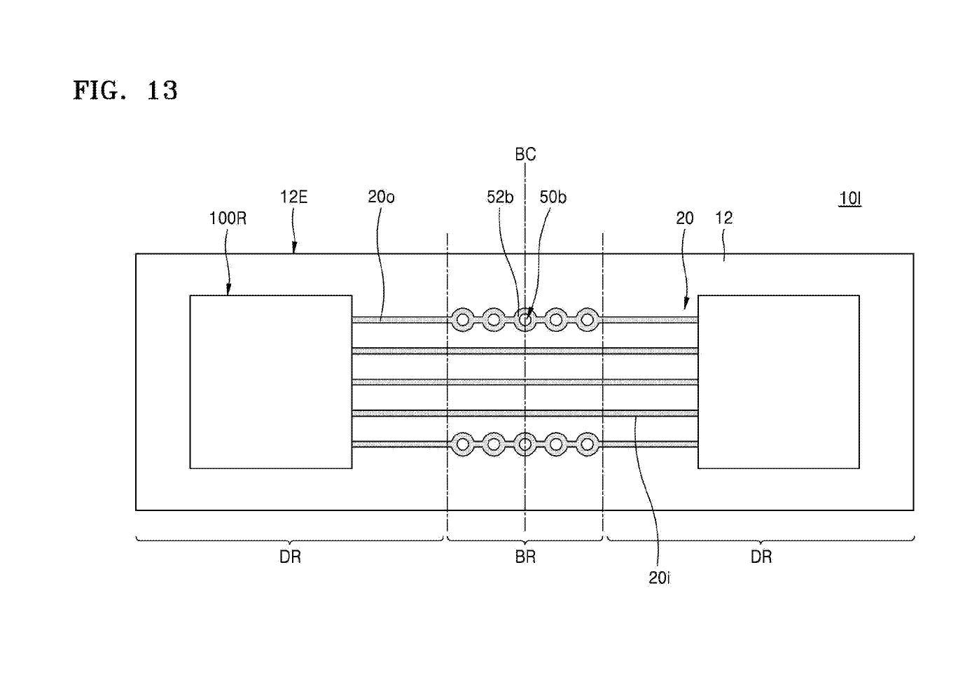

FIG. 13 is a plan view illustrating essential parts of a PCB 10l according to an example embodiment.

Referring to FIG. 13, the PCB 10i includes the base substrate 12 and the connection line 20 formed on the base substrate 12. The base substrate 12 included in the PCB 10l may include the bending region BR having both edges 12E and the mounting regions DR extending from both ends of the bending region BR.

The base substrate 12 may include an opening 50b formed in the bending region BR. The opening 50b may be formed in the connection line 20. The opening 50b may be formed in the outer connection line 20o that is the closest to each or at least one of both edges 12E of the bending region BR from among a plurality of the connection lines 20. The opening 50b may not be formed in the inner connection lines 20i other than the outer connection line 20o. A plurality of the openings 50b may be arranged to form a line along the outer connection line 20o in the bending region BR. One of the plurality of openings 50b arranged to form the line along the outer connection line 20o may be located on the virtual bending central line BC that connects both edges 12E of the bending region BR. Widths of the plurality of openings 50b arranged to form the line along the outer connection line 20o may be substantially constant.

The opening 50b may be a through-hole that is formed in the base substrate 12 and extends from a top surface of the base substrate 12 to a bottom surface of the base substrate 12. A boundary of the opening 50b may have a circular shape.

A guard pattern 52b may be formed along the boundary of the opening 50b on the top surface and/or the bottom surface of the base substrate 122. The guard pattern 52b may have a substantially constant width along the boundary of the opening 50b. The guard pattern 52b may serve as a part of the outer connection line 20o. That is, the outer connection line 20o and the guard pattern 52b may be integrally formed with each other. A width of the outer connection line 20o and a width of the guard pattern 52b may be substantially equal to each other.

In the PCB 10l according to the example embodiment, even when cracks occur and propagate on the edge 12E of the bending region BR, the cracks may meet the opening 50b and thus may be substantially prevented from further propagating into the base substrate 12. Accordingly, even when the cracks propagate to a portion of the guard pattern 52b formed on the outer connection line 20o, that is, to a portion of the guard pattern 52b that is adjacent to the edge 12E from the opening 50b, the outer connection line 20o may be substantially prevented from being shorted due to a portion of the guard pattern 52b that is far from the edge 12E, thereby improving the reliability of the electronic apparatus 1 including the PCB 10l.

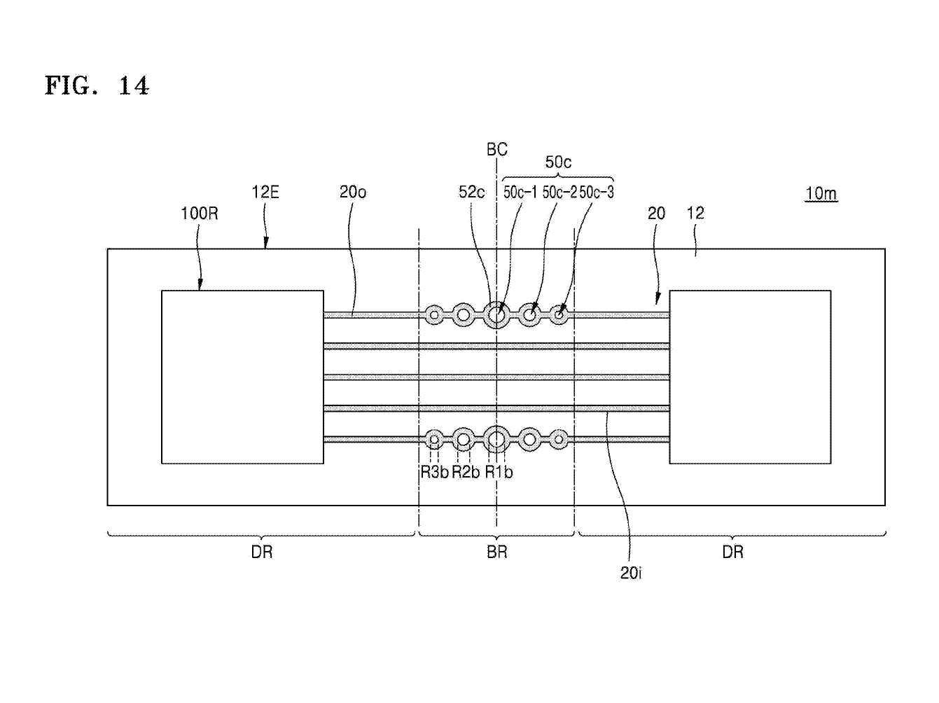

FIG. 14 is a plan view illustrating essential parts of a PCB 10m according to an example embodiment.

Referring to FIG. 14, the PCB 10m includes the base substrate 12 and the connection line 20 formed on the base substrate 12. The base substrate 12 included in the PCB 10m may include the bending region BR having both edges 12E and the mounting regions DR extending from both ends of the bending region BR.

The base substrate 12 may include an opening 50c formed in the bending region BR. The opening 50c may be formed in the connection line 20. The opening 50c may be formed in the outer connection line 20o that is the closest to each or at least one of both edges 12E of the bending region BR from among a plurality of the connection lines 20. The opening 50c may not be formed in the inner connection lines 20i other than the outer connection line 20o. A plurality of the openings 50c may be arranged to form a line along the outer connection line 20o in the bending region BR. One of the plurality of openings 50c arranged to form the line along the outer connection line 20o may be located on the virtual bending central line BC that connects both edges 12E of the bending region BR.

Widths of the plurality of openings 50c arranged to form the line along the outer connection line 20o may not be constant. For example, widths R3b of openings 50c-3 formed on both ends of the line may be less than widths R1b and R2b of openings 50c-1 and 50c-2 formed in the line from among the plurality of openings 50c arranged to form the line along the outer connection line 20o. For example, the width R1b of the opening 50c-1 located on the virtual bending central line BC is the largest and the widths R3b of the openings 50c-3 formed on both ends of the line may be the smallest from among the plurality of openings 50c arranged to form the line along the outer connection line 20o. For example, widths of the plurality of openings 50c arranged to form the line along the outer connection line 20o may decrease toward both ends of the line from the center of the virtual bending central line BC.

The opening 50c may be a through-hole that is formed in the base substrate 12 and extends from a top surface of the base substrate 12 to a bottom surface of the base substrate 12. A boundary of the opening 50c may have a circular shape.

A guard pattern 52c may be formed along the boundary of the opening 50c on the top surface and/or the bottom surface of the base substrate 12. The guard pattern 52c may have a substantially constant width along the boundary of the opening 50c. The guard pattern 52c may serve as a part of the outer connection line 20o. That is, the outer connection line 20o and the guard pattern 52c may be integrally formed with each other. A width of the outer connection line 20o and a width of the guard pattern 52c may be substantially equal to each other.

In the PCB 10m according to the example embodiment, even when cracks occur and propagate on the edge 12E of the bending region BR, the cracks may meet the opening 50c and thus may be substantially prevented from further propagating into the base substrate 12. Accordingly, even when the cracks propagate to a portion of the guard pattern 652c formed on the outer connection line 20o, that is, to a portion of the guard pattern 52c that is adjacent to the edge 12E from the opening 50c, the outer connection line 20o may be substantially prevented from being shorted due to a portion of the guard pattern 562c that is far from the edge 12E from the opening 50c, thereby improving the reliability of the electronic apparatus 1 including the PCB 10m.

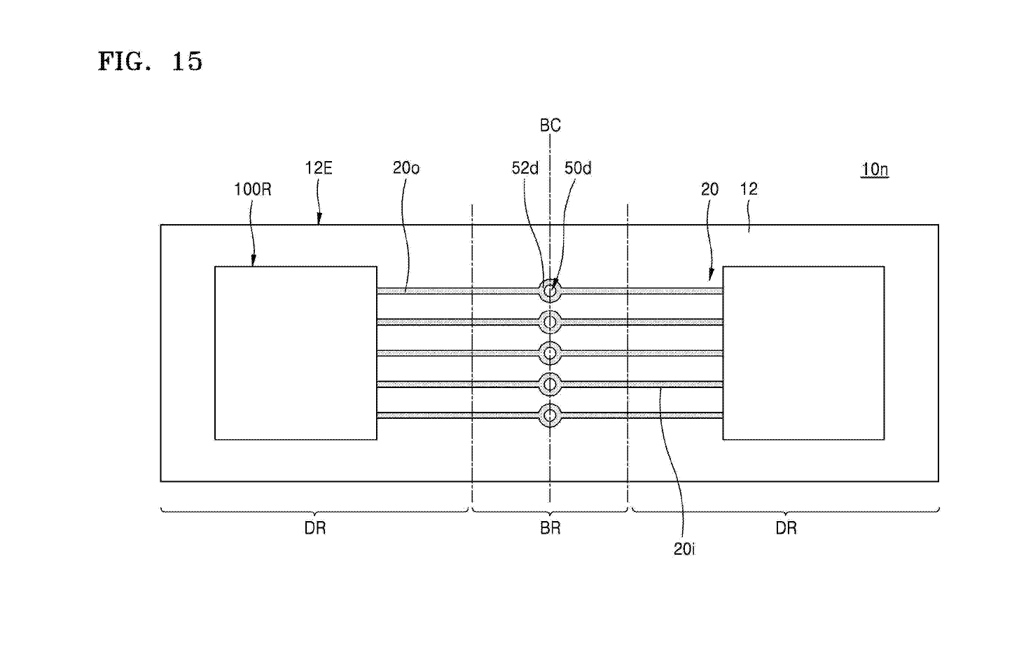

FIG. 15 is a plan view illustrating essential parts of a PCB 10n according to an example embodiment.

Referring to FIG. 15, the PCB 10n includes the base substrate 12 and the connection line 20 formed on the base substrate 122. The base substrate 12 included in the PCB 10n may include the bending region BR having both edges 12E and the mounting regions DR extending from both ends of the bending region BR.

The base substrate 12 may include an opening 50d formed in the bending region BR. The opening 50d may be formed in the connection line 20. The opening 50d may be formed in each or at least one of a plurality of the connection lines 20. That is, the opening 50d may be formed in each or at least one of the outer connection line 20o and the inner connection lines 20i. The opening 50d formed in each connection line 20 may be located on the virtual bending central line BC that connects both edges 12E of the bending region BR.

The opening 50d may be a through-hole that is formed in the base substrate 12 and extends from a top surface of the base substrate 12 to a bottom surface of the base substrate 12. A boundary of the opening 50d may have a circular shape.

A guard pattern 52d may be formed along the boundary of the opening 50d on the top surface and/or the bottom surface of the base substrate 12. The guard pattern 52d may have a substantially constant width along the boundary of the opening 50d. The guard pattern 52d may serve as a part of the connection line 20. That is, the connection line 20 and the guard pattern 52d may be integrally formed with each other. A width of the connection line 20 and a width of the guard pattern 52d may be substantially equal to each other.

In the PCB 10n according to the example embodiment, cracks may be substantially prevented from propagating due to the opening 50d. Even when a portion of the connection line 20 that is located on the virtual bending central line BC is damaged by stress caused by fatigue, the connection line 20 may be substantially prevented from being shorted. That is, since the connection line 20 has two paths about the opening 50d on the virtual bending central line BC due to the guard pattern 52d that surrounds the opening 50d, even when one path is damaged, the connection line 20 may be substantially prevented from being shorted due to the other path, thereby improving the reliability of the electronic apparatus 1 including the PCB 10n.

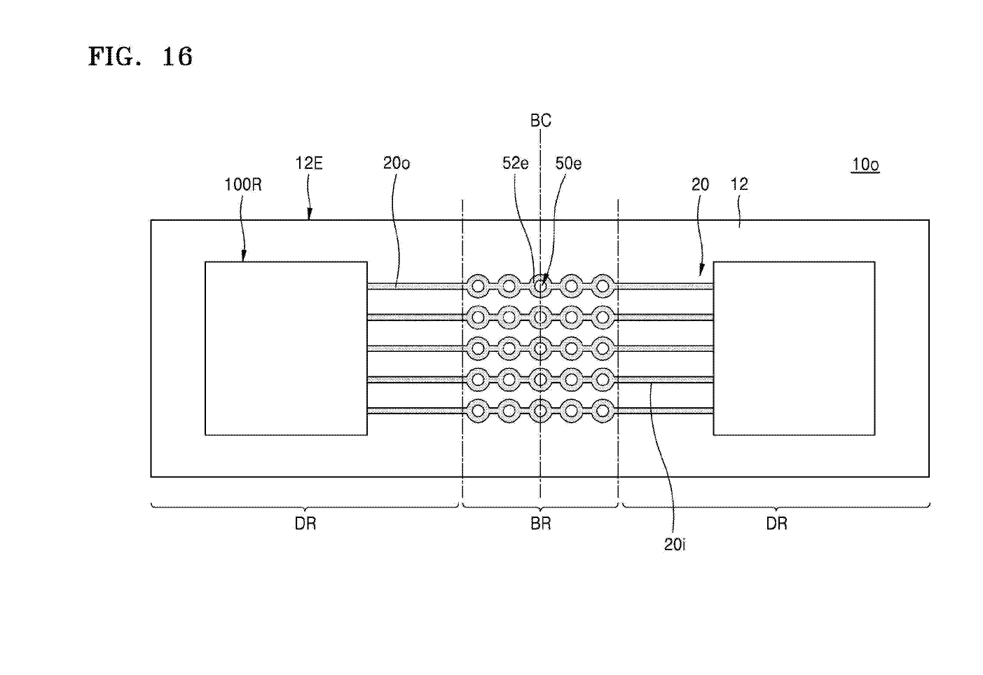

FIG. 16 is a plan view illustrating essential parts of a PCB 10o according to an example embodiment.

Referring to FIG. 16, the PCB 10o includes the base substrate 12 and the connection line 20 formed on the base substrate 12. The base substrate 12 included in the PCB 10o may include the bending region BR having both edges 12E and the mounting regions DR extending from both ends of the bending region BR.

The base substrate 12 may include an opening 50e formed in the bending region BR. The opening 50e may be formed in the connection line 20. The opening 50e may be formed in each or at least one of a plurality of the connection lines 20. That is, the opening 50e may be formed in each or at least one of the outer connection line 20o and the inner connection lines 20i. A plurality of the openings 50e may be arranged to form a line along each connection line 20 in the bending region BR. One of the plurality of openings 50e arranged to form the line along the connection line 20 may be located on the virtual bending central line BC that connects both edges 12E of the bending region BR. Widths of the plurality of openings 50e arranged to form the line along the connection line 20 may be substantially constant.

The opening 50e may be a through-hole that is formed in the base substrate 12 and extends from a top surface of the base substrate 12 to a bottom surface of the base substrate 12. A boundary of the opening 50e may have a circular shape.

A guard pattern 52e may be formed along the boundary of the opening 50e on the top surface and/or the bottom surface of the base substrate 12. The guard pattern 52e may have a substantially constant width along the boundary of the opening 50e. The guard pattern 52e may serve as a part of the connection line 20. That is, the connection line 20 and the guard pattern 52e may be integrally formed with each other. A width of the connection line 20 and a width of the guard pattern 52e may be substantially equal to each other.

In the PCB 10o according to the example embodiment, cracks may be substantially prevented from propagating due to the opening 50e. Also, even when a portion of the connection line 20 that is disposed in the bending region BR is damaged by stress caused by fatigue, the connection line 20 may be substantially prevented from being shorted. That is, since the connection line 20 includes two paths about the opening 50e due to the guard pattern 52e that surrounds the opening 50e, even when one path is damaged, the connection line 20 may be substantially prevented from being shorted due to the other path, thereby improving the reliability of the electronic apparatus 1 including the PCB 10o.

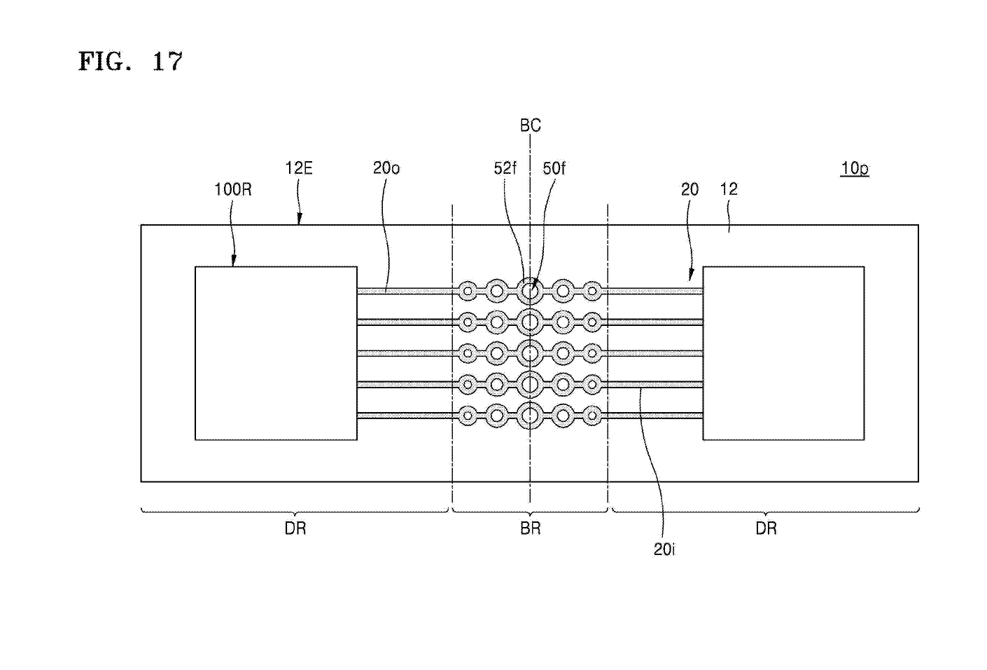

FIG. 17 is a plan view illustrating essential parts of a PCB 10p according to an example embodiment.

Referring to FIG. 17, the PCB 10p includes the base substrate 12 and the connection line 20 formed on the base substrate 12. The base substrate 12 included in the PCB 10p may include the bending region BR having both edges 12E and the mounting regions DR extending from both ends of the bending region BR.

The base substrate 12 may include an opening 50f formed in the bending region BR. The opening 50f may be formed in the connection line 20. The opening 50f may be formed in each or at least one of a plurality of the connection lines 20. A plurality of the openings 50f may be arranged to form a line along each or at least one of the connection lines 20 in the bending region BR. One of the plurality of openings 50f arranged to form the line along the connection line 20 may be located on the virtual bending central line BC that connects both edges 12E of the bending region BR,

The PCB 10p is similar to or the same as the PCB 10o of FIG. 16 except that the opening 50f formed in the connection line 20 is similar to or the same as the opening 50c formed in the outer connection line 20o of FIG. 14, and thus a detailed explanation thereof will not be given. That is, a width of the opening 50f located on the virtual bending central line BC from among the plurality of openings 50f formed in the connection line 20 may be the largest.

In the PCB 10p according to the example embodiment, cracks may be substantially prevented from propagating due to the opening 50f. Even when a portion of the connection line 20 that is disposed in the bending region BR is damaged by stress caused by fatigue, the connection line 20 may be substantially prevented from being shorted. That is, since the connection line 20 includes two paths about the opening 50f due to a guard pattern 52f that surrounds the opening 50f, even when one path is damaged, the connection line 20 may be substantially prevented from being shorted due to the other path, thereby improving the reliability of the electronic apparatus 1 including the PCB 10p.

Although the openings 30a, 30b, 30c, 30d, 30e, 30f, 30g, 40a, 40b, 40c, 40d, 40e, 40f, and 40g are each formed in a portion of the base substrate 12 on which the connection line 20 is not formed in FIGS. 2 through 11 whereas the openings 50a, 50b, 50c, 50d, 50e, and 50f are formed in the connection line 20 in FIGS. 12 through 17, any combination may be made. That is, a PCB including at least one of the openings 30a, 30b, 30c, 30d, 30e, 30f, 30g, 40a, 40b, 40c, 40d, 40e, 40f, and 40g of FIGS. 2 through 11 and at least one of the openings 50a, 50b, 50c, 50d, 50e, and 50f of FIGS. 12 through 17 may be provided without departing from the scope of the inventive concepts.

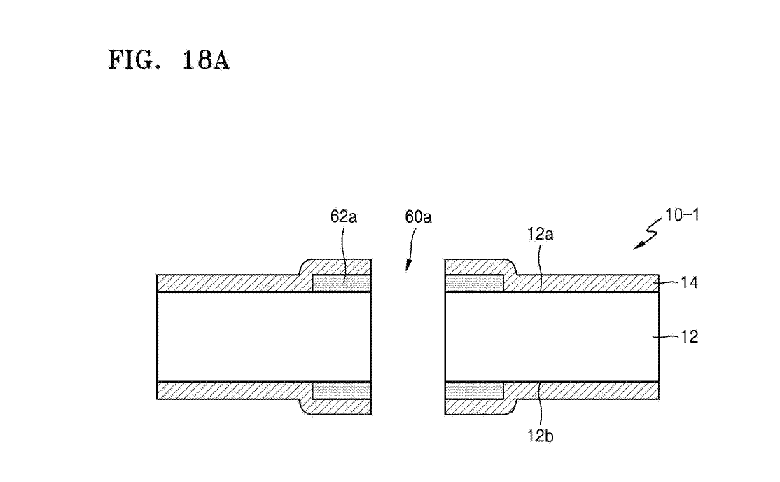

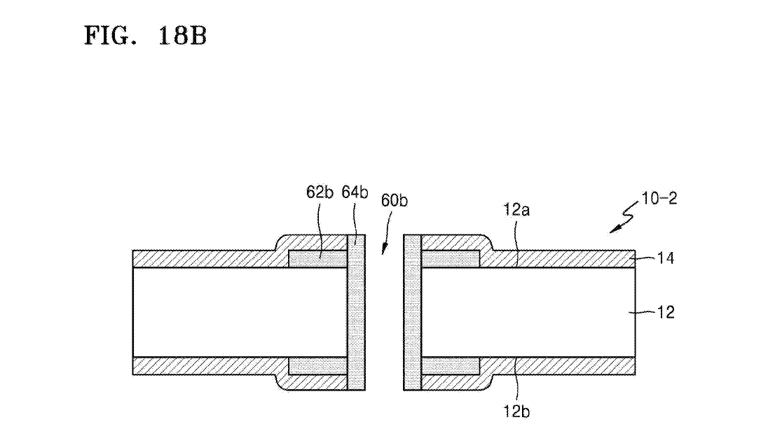

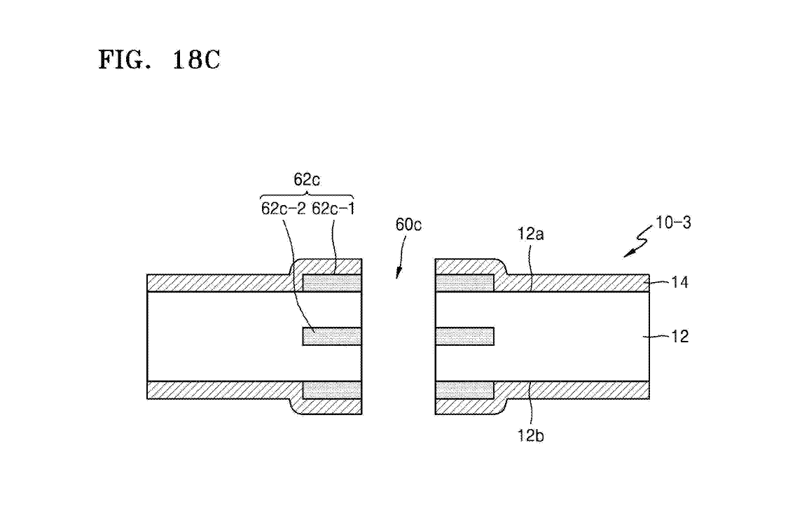

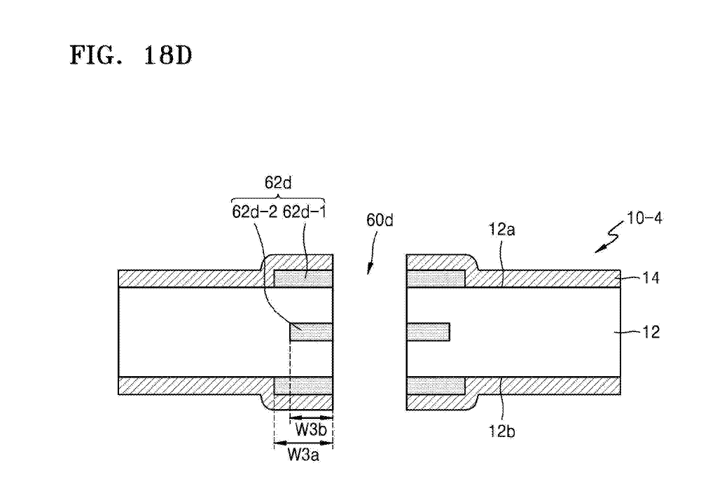

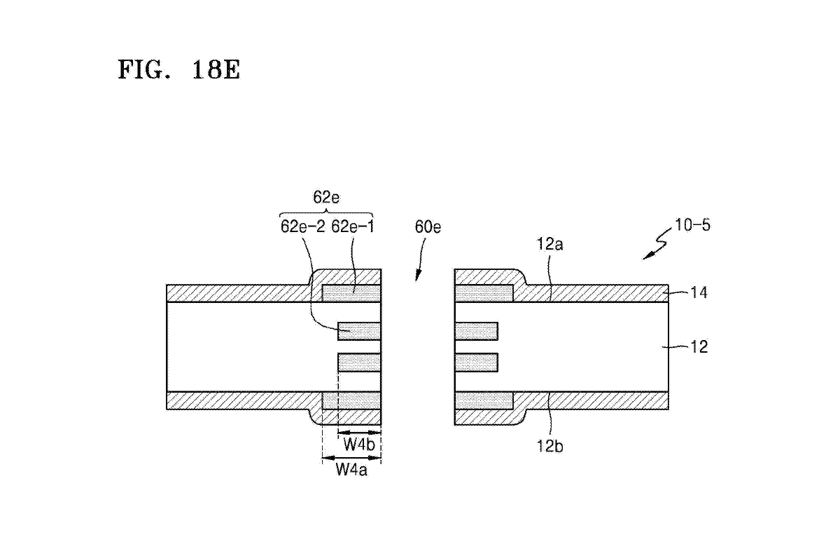

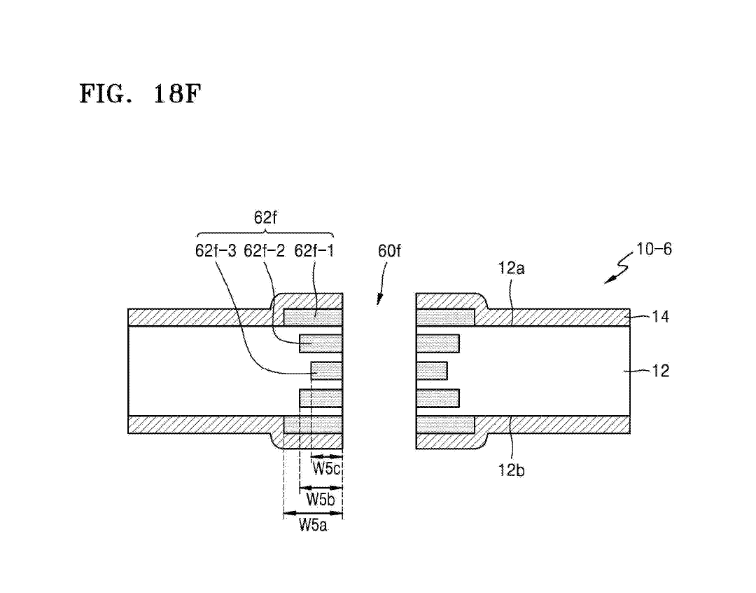

FIGS. 18A through 18F are cross-sectional views each illustrating essential parts of a PCB included in the electronic apparatus 1 of FIG. 1. In particular, FIGS. 18A through 18F are cross-sectional views illustrating portions of a PCB corresponding to the openings 30a, 30b, 30c, 30d, 30e, 30f, 30g, 40a, 40b, 40c, 40d, 40e, 40f, 40g, 50a, 50b, 50c, 50d, 50e, and 50f of FIGS. 2 through 17. In FIGS. 18A through 18F, the same elements as those described above are denoted by the same reference numerals, and a repeated explanation thereof will not be given.

FIG. 18A is a partial enlarged cross-sectional view of a PCB 10-1 according to an example embodiment.

Referring to FIG. 18A, the PCB 10-1 includes the base substrate 12 including an opening 60a. A guard pattern 62a may be formed along a boundary of the opening 60a on each or at least one of a top surface 12a and a bottom surface 12b of the base substrate 12. The guard pattern 62a may have a substantially constant width along the boundary of the opening 60a. A width of the guard pattern 62a formed on the top surface 12a of the base substrate 12 and a width of the guard pattern 62a formed on the bottom surface 12b of the base substrate 12 may be substantially equal to each other.

The PCB 10-1 may further include a cover layer 14 that is an insulating layer and is formed on each or at least one of the top surface 12a and the bottom surface 12b of the base substrate 12. The cover layer 14 may cover the guard pattern 62a formed on the top surface 12a and the guard pattern 62a formed on the bottom surface 12b of the base substrate 12.

The cover layer 14 may be formed of or include, for example, a PI film, a PET film, a flexible solder mask, a PIC, or a photo-imageable solder resist. The cover layer 14 may be formed, for example, by directly coating the base substrate 12 with thermosetting ink by using silk-screen printing or inkjet printing and then performing thermal curing. The cover layer 14 may be formed, for example, by entirely coating the base substrate 12 with a photo-imageable solder resist by using screen printing or spray coating, removing a unnecessary portion through exposure and development, and then performing thermal curing. The cover layer 14 may be formed, for example, by laminating a PI film or a PET film onto the base substrate 12.

FIG. 18B is a partial enlarged cross-sectional view of a PCB 10-2 according to an example embodiment.

Referring to FIG. 18B, the PCB 10-2 includes the base substrate 12 including an opening 60b. A guard pattern 62b may be formed along a boundary of the opening 60b on each or at least one of the top surface 12a and the bottom surface 12b of the base substrate 12. The guard pattern 62b may have a substantially constant width along the boundary of the opening 60b. A width of the guard pattern 62b formed on the top surface of the base substrate 12 and a width of the guard pattern 62b formed on the bottom surface 12b may be substantially equal to each other.

A side wall pattern 64b that conformably covers an inner side wall of the opening 60b may be formed in the opening 60b. The side wall pattern 64b may be formed of or include, for example, copper or a copper alloy. The side wall pattern 64b may be formed, for example, by using electroplating or electroless plating. The side wall pattern 64b may substantially prevent cracks from occurring and propagating in the base substrate 12.

Although not shown, a side wall pattern that conformably covers a side wall of each or at least one of openings 60c, 60d, 60e, and 60f of FIGS. 18C through 18F may be further formed in each or at least one of the openings 60c, 60d, 60e, and 60f.

FIG. 18C is a partial enlarged cross-sectional view of a PCB 10-3 according to an example embodiment.

Referring to FIG. 18C, the PCB 10-3 includes the base substrate 12 including the opening 60c. A guard pattern 62c may be formed along a boundary of the opening 60c on the base substrate 12. The guard pattern 62c may have a substantially constant width along the boundary of the opening 60c. The guard pattern 62c may include a surface guard pattern 62c-1 formed on each or at least one of the top surface 12a and the bottom surface 12b of the base substrate 12 and a buried guard pattern 62c-2 formed in the base substrate 12.

The buried guard pattern 62c-2 may be formed along with a connection line to have a single-layer structure in the base substrate 12.

A width of the surface guard pattern 62c-1 formed on each or at least one of the top surface 12a and the bottom surface 12b of the base substrate 12 and a width of the buried guard pattern 62c-2 formed in the base substrate 12 may be substantially equal to each other.

FIG. 18D is a partial enlarged cross-sectional view of a PCB 10-4 according to an example embodiment.

Referring to FIG. 18D, the PCB 10-4 includes the base substrate 12 including the opening 60d. A guard pattern 62d may be formed along a boundary of the opening 60d on the base substrate 12. The guard pattern 62d may have a substantially constant width along the boundary of the opening 60d. The guard pattern 62d may include a surface guard pattern 62d-1 formed on each or at least one of the top surface 12a and the bottom surface 12b of the base substrate 12 and a buried guard pattern 62d-2 formed in the base substrate 12.

When the PCB 10-4 is repeatedly bent as shown in FIG. 1, larger compression and/or tension may occur on the top surface 12a and the bottom surface 12b than in the base substrate 12. Accordingly, since more stress caused by fatigue may be concentrated on the top surface 12a and the bottom surface 12b than in the base substrate 12, a width W3a of the surface guard pattern 62d-1 formed on each or at least one of the top surface 12a and the bottom surface 12b of the base substrate 12 may be greater than a width W3b of the buried guard pattern 62d-2 formed in the base substrate 12.

FIG. 18E is a partial enlarged cross-sectional view of a PCB 10-5 according to an example embodiment.

Referring to FIG. 18E, the PCB 10-5 includes the base substrate 12 including the opening 60e. A guard pattern 62e may be formed along a boundary of the opening 60e. The guard pattern 62e may have a substantially constant width along the boundary of the opening 60e. The guard pattern 62e may include a surface guard pattern 62e-1 formed on each or at least one of the top surface 12a and the bottom surface 12b of the base substrate 12 and a buried guard pattern 62e-2 formed in the base substrate 12. The PCB 10-5 may include the buried guard pattern 62e-2 that is formed to have a multi-layer structure.

A width W4a of the surface guard pattern 62e-1 formed on each or at least one of the top surface 12a and the bottom surface 12b of the base substrate 12 may be greater than a width W4b of the buried guard pattern 62e-2 formed in the base substrate 12. Widths of layers of the multi-layer structure of the buried guard pattern 62e-2 may be substantially equal to one another.

FIG. 18F is a partial enlarged cross-sectional view of a PCB 10-6 according to an example embodiment.

Referring to FIG. 18F, the PCB 10-6 includes the base substrate 12 including the opening 60f. A guard pattern 62f may be formed along a boundary of the opening 60f on the base substrate 12. The guard pattern 62f may have a substantially constant width along the boundary of the opening 60f. The guard pattern 62f may include a surface guard pattern 62f-1 formed on each or at least one of the top surface 12a and the bottom surface 12b of the base substrate 12 and buried guard patterns 62f-2 and 62f-3 formed in the base substrate 12. The PCB 10-6 may include the buried guard patterns 62f-2 and 62f-3 that are formed to have a multi-layer structure.

A width W5a of the surface guard pattern 62f-1 formed on each or at least one of the top surface 12a and the bottom surface 12b of the base substrate 12 may be greater than widths W5b and W5c of the buried guard patterns 62f-2 and 62-f3 formed in the base substrate 12. From among the buried guard patters 62f-2 and 62f-3, the width W5c of the buried guard pattern 62f-3 that is relatively adjacent to the center of the base substrate 12 may be less than the width W5b of the buried guard pattern 62f-2 that is relatively adjacent to the top surface 12a or the bottom surface 12b of the base substrate 12. That is, a width of the guard pattern 62f may decrease inward away from a surface of the base substrate 12.

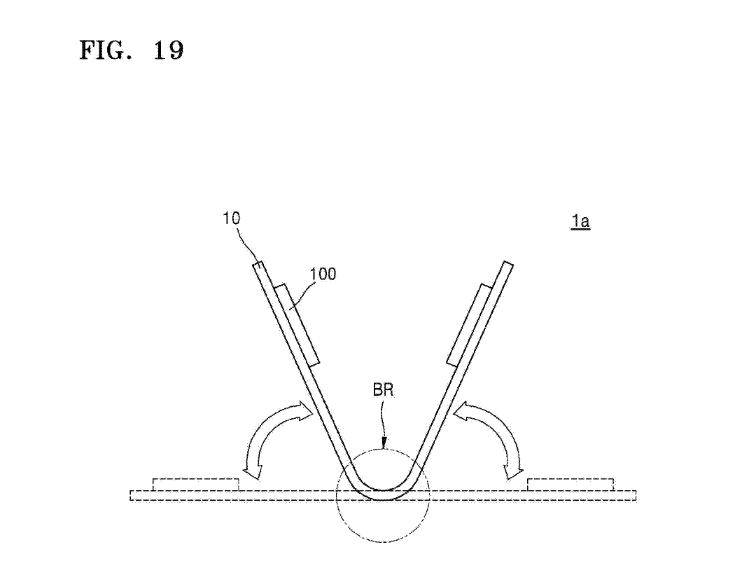

FIG. 19 is a schematic view for explaining the PCB 10 according to an example embodiment.

Referring to FIG. 19, an electronic apparatus 1a includes the PCB 10 and the device 100 mounted on the PCB 10. When the electronic apparatus 1 is repeatedly bent during use, deformation in the bending region BR may be different on both surfaces of the PCB 10. For example, compressive deformation may occur on one surface of the PCB 10 and tensile deformation may occur on the other surface of the PCB 10. Accordingly, stress caused by fatigue may be different on both surfaces of the PCB 10 included in the electronic apparatus 1a.

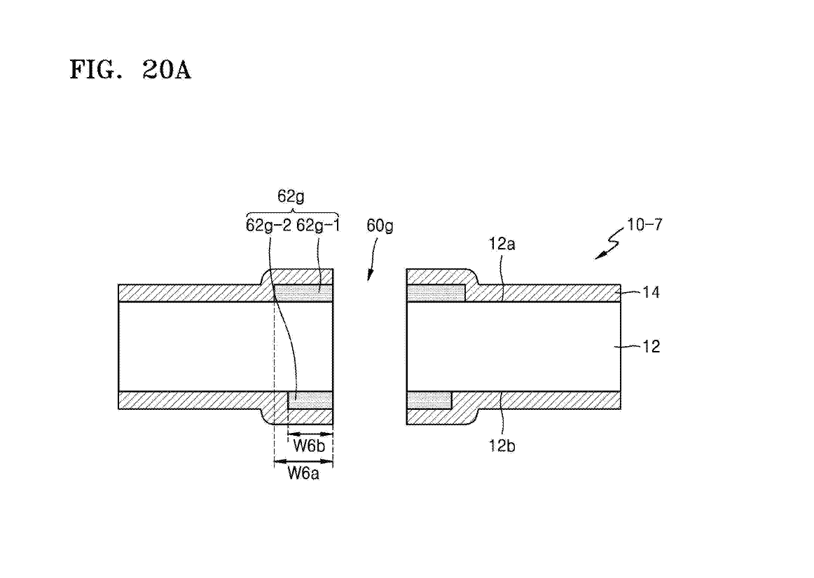

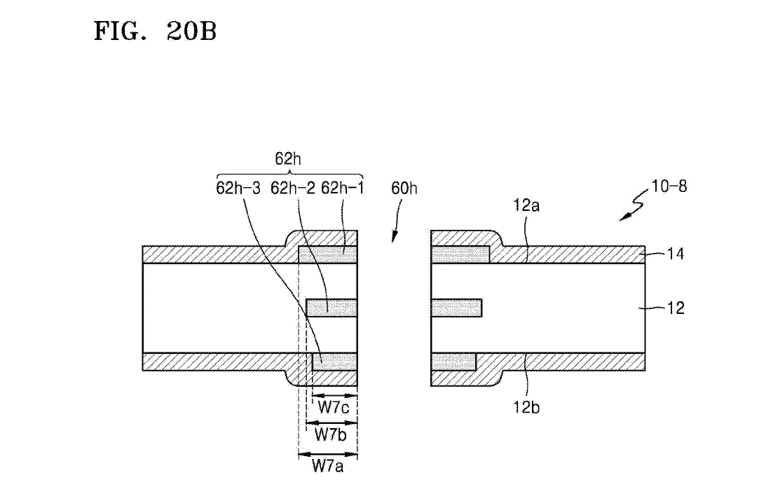

FIGS. 20A and 20B are cross-sectional views illustrating essential parts of a PCB included in the electronic apparatus 1a of FIG. 19. In particular, FIGS. 20A and 20B are cross-sectional views illustrating portions of a PCB corresponding to the openings 30a, 30b, 30c, 30d, 30e, 30f, 30g, 40a, 40b, 40c, 40d, 40e, 40f, 40g, 50a, 50b, 50c, 50d, 50e, and 50f of FIGS. 2 through 17. In FIGS. 20A and 20B, the same elements as those described above are denoted by the same reference numerals and a repeated explanation thereof will not be given.

Although not shown, a side wall pattern that conformably covers a side wall of each or at least one of openings 60g and 60h of FIGS. 20A and 20B may be further formed in each or at least one of the openings 60g and 60h, like in FIG. 18B.

Also, FIGS. 18A through 18F may be cross-sectional views each illustrating essential parts of a PCB included in the electronic apparatus 1a of FIG. 19.

FIG. 20A is a partial enlarged cross-sectional view of a PCB 10-7 according to an example embodiment.

Referring to FIG. 20A, the PCB 10-7 includes the base substrate 12 including the opening 60g. A guard pattern 62g may be formed along a boundary of the opening 60g. The guard pattern 62g may have a substantially constant width along the boundary of the opening 60g. The guard pattern 62g may include an upper guard pattern 62g-1 formed on the top surface 12a of the base substrate 12 and a lower guard pattern 62g-2 formed on the bottom surface 12b of the base substrate 12.

For example, more stress caused by fatigue may be applied to the top surface 12a of the base substrate 12 than to the bottom surface 12b of the base substrate 12 when the electronic apparatus 1a is repeatedly bent during use as described above with reference to FIG. 19. Accordingly, a width W6a of the upper guard pattern 62g-1 may be greater than a width W6b of the lower guard pattern 62g-2.

FIG. 20B is a partial enlarged cross-sectional view of a PCB 10-8 according to an example embodiment.

Referring to FIG. 20B, the PCB 10-8 includes the base substrate 12 including the opening 60h. A guard pattern 62h may be formed along a boundary of the opening 60h on the base substrate 12. The guard pattern 62h may have a substantially constant width along the boundary of the opening 60h. The guard pattern 62h may include an upper guard pattern 62h-1 formed on the top surface 12a of the base substrate 12, a lower guard pattern 62h-3 formed on the bottom surface 12b of the base substrate 12, and a buried guard pattern 62h-2 formed in the base substrate 12.

A width W7a of the upper guard pattern 62h-1 may be greater than a width W7c of the lower guard pattern 62h-3, and a width W7b of the buried guard pattern 62h-2 may be less than the width W7a of the upper guard pattern 62h-1 and may be greater than the width W7c of the lower guard pattern 62h-3.

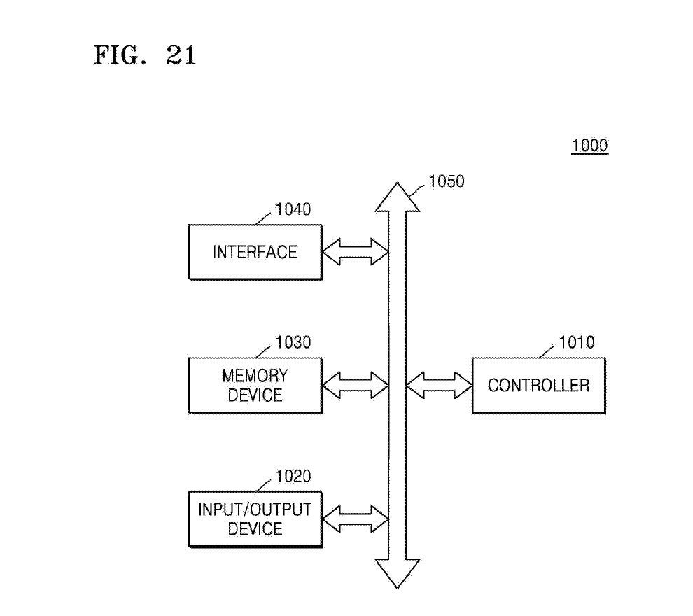

FIG. 21 is a block diagram illustrating a configuration of a system 1000 according to an example embodiment.

Referring to FIG. 21, the system 1000 includes a controller 1010, an input/output device 1020, a memory device 1030, and an interface 1040. The system 1000 may be a wearable device. In an example embodiment, the wearable device may be a watch-type wearable device, a wristband-type wearable device, or a glasses-type wearable device. The controller 1010 for controlling an executive program in the system 1000 may include a microprocessor, a digital signal processor, a microcontroller, or the like. The input/output device 1020 may be used to input or output data of the system 1000. The system 1000 may be connected to an external apparatus, for example, a PC or a network, by using the input/output device 1020, and may exchange data with the external apparatus. The input/output device 1020 may be or include, for example, a keypad, a button, a sound device, or a display device. The memory device 1030 may store code and/or data for operating the controller 1010, or may store data processed by the controller 1010.

The interface 1040 may be a path through which data is transmitted between the system 1000 and the external apparatus. The controller 1010, the input/output device 1020, the memory device 1030, and the interface 1040 may communicate with one another via a bus 1050.

The system 1000 may include at least one of the PCBs of FIGS. 1 through 20B.

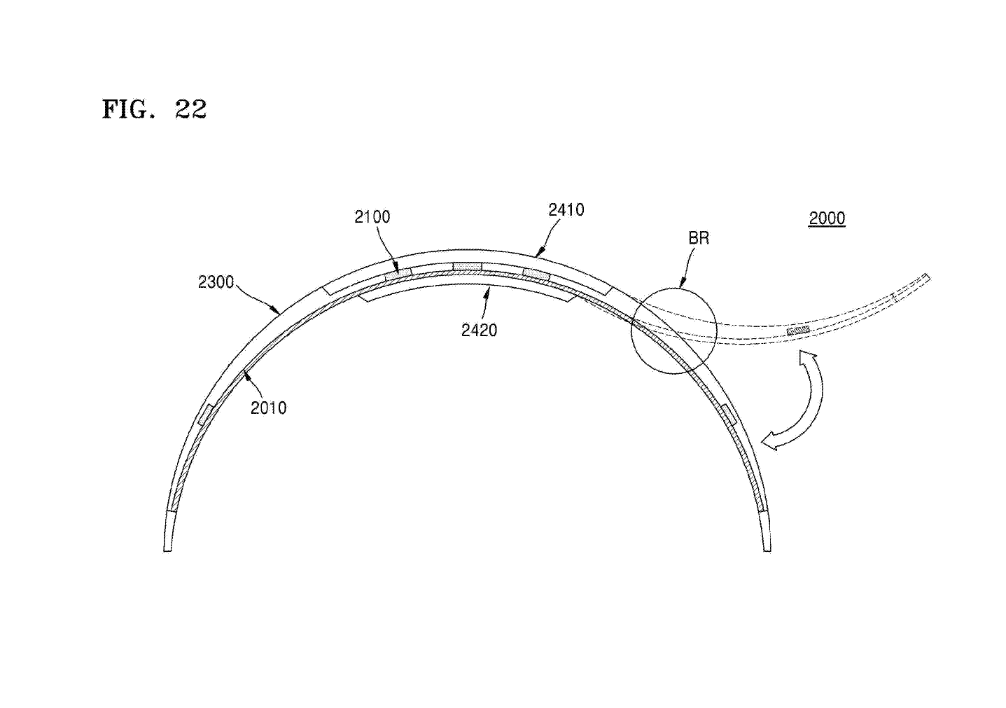

FIG. 22 is a cross-sectional view of an electronic apparatus 2000 according to an example embodiment. In FIG. 22, the electronic apparatus 2000 including a PCB may be or include, for example, a wristband.

Referring to FIG. 22, the electronic apparatus 2000 includes a PCB 2010 and a device 2100 mounted on the PCB 2010. The PCB 2010 may be at least one of the PCBs of FIGS. 1 through 20B. The device 2100 may be an electrical/electronic component used to drive the electronic apparatus 2000. The electronic apparatus 2000 may include an upper body 2410, a lower body 2420, and a cover 2300. The cover 2300 may cover a surface of the electronic apparatus 2000 in order to protect elements included in the electronic apparatus 2000.

The upper body 2410 and the lower body 2420 may be used to maintain a main shape of the electronic apparatus 2000. Alternatively, an input/output device of the electronic apparatus 2000 may be disposed on the upper body 2410. A sensor may be disposed on the lower body 2420.

The device 2100 that is relatively important to drive the electronic apparatus 2000 may be disposed between the upper body 2410 and the lower body 2420. Although a portion of the PCB 2010 disposed between the upper body 2410 and the lower body 2420 is curved, the portion may be substantially prevented from being bent because deformation is limited by the upper body 2410 and the lower body 2420. That is, the portion of the PCB 2010 disposed between the upper body 2410 and the lower body 2420 may be the mounting region DR of FIGS. 1 through 20B.

A portion of the electronic apparatus 2000 that is adjacent to the upper body 2410 and the lower body 2420 may be the bending region BR that is repeatedly bent in order to attach or detach the electronic apparatus 2000.

A PCB according to the inventive concepts may substantially prevent cracks from occurring or a connection line from being shorted due to stress caused by fatigue when an electronic apparatus including the PCB is repeatedly bent.

Accordingly, the reliability of the electronic apparatus including the PCB may be guaranteed.

While the inventive concepts has been particularly shown and described with reference to embodiments thereof, it will be understood that various changes in form and details may be made therein without departing from the spirit and scope of the following claims.

1. A printed circuit board (PCB) comprising:
a base substrate having a first edge and a second edge on opposite sides of the base substrate, the base substrate having a bending region including an opening adjacent to the first edge, an opening adjacent to the second edge, and mounting regions extending from opposite ends of the bending region and including device mounting portions;
a connection line on the base substrate and crossing the bending region, the connection line being configured to connect the device mounting portions; and a guard pattern on at least one of a top surface and a bottom surface of the base substrate along a boundary of at least one of the openings.

2. The PCB of claim 1, wherein the opening adjacent to the first edge and the opening adjacent to the second edge face each other.

3.-4. (canceled)

5. The PCB of claim 1, wherein at least one of the openings is a through-hole in the base substrate.

6.-7. (canceled)

8. The PCB of claim 1, wherein the opening adjacent to the first edge is recessed from the first edge of the base substrate, and the opening adjacent to the second edge is recessed from the second edge of the base substrate.

9. (canceled)

10. The PCB of claim 1, wherein the openings comprise a first opening that is recessed from one of the first and second edges of the base substrate, and a second opening that is a through-hole in the base substrate spaced apart from the first opening.

11.-12. (canceled)

13. The PCB of claim 1, wherein the openings are in the connection line, and the guard pattern is part of the connection line.

14.-17. (canceled)

18. The PCB of claim 1, wherein the openings are on a virtual bending central line connecting the first edge and the second edge.

19. The PCB of claim 18, wherein a plurality of the openings are located toward ends of the bending region from the virtual bending central line, along a direction crossing the virtual bending central line.

20. (canceled)

21. A printed circuit board (PCB) comprising:
a base substrate having a first edge and a second edge on opposite sides of the base substrate, the base substrate having a bending region that includes at least one pair of openings respectively adjacent to the first edge and to the second edge and facing each other, and mounting regions that extend from opposite ends of the bending region and that include device mounting portions;
a connection line on the base substrate and crossing bending region, the connection line being configured to connect the device mounting portions; and
a guard pattern on at least one of a top surface and a bottom surface of the base substrate along a boundary of at least one of the at least one pair of openings.

22. The PCB of claim 21, wherein the at least one of the at least one pair of openings is a through-hole in the base substrate that extends from the top surface of the base substrate to the bottom surface of the base substrate, and
the opening adjacent to the first edge is between the connection line and the first edge, and the opening adjacent to the second edge is between the connection line and the second edge.

23. The PCB of claim 21, wherein the boundary of at least one of the at least one pair of openings is substantially arc shaped, and
the opening adjacent to the first edge is recessed from the first edge, and the opening adjacent to the second edge is recessed from the second edge.

24. The PCB of claim 21, wherein the at least one pair of openings are formed in the connection line, and
the guard pattern is integrally formed with the connection line.

25. The PCB of claim 21, wherein the at least one pair of openings comprise a first opening that is recessed from one of the first and second edges of the base substrate and has a boundary that is substantially arc shaped, and a second opening that is a through-hole between the first opening and the connection line, and
the guard pattern includes a first guard pattern along the boundary of the first opening and a second guard pattern along the boundary of the second opening spaced apart from the first guard pattern.

26. The PCB of claim 21, further comprising a side wall pattern that conformably covers an inner side wall of at least one of the at least one pair of openings.

27. The PCB of claim 21, wherein the guard pattern comprises an upper guard pattern on the top surface of the base substrate and a lower guard pattern on the bottom surface of the base substrate, and
a width of the upper guard pattern and a width of the lower guard pattern are substantially equal to each other.

28.-29. (canceled)

30. The PCB of claim 21, wherein the guard pattern comprises an upper guard pattern on the top surface of the base substrate and a lower guard pattern on the bottom surface of the base substrate, and a width of the upper guard pattern is greater than a width of the lower guard pattern.

31. (canceled)

32. A printed circuit board (PCB) comprising:
a base substrate including at least one opening in at least one edge thereof in a bending region configured to be bent;
at least one guard pattern along a boundary of the at least one opening; and
a connection line on the base substrate and crossing the bending region, the connection line electrically connecting at least two portions on opposite sides of the bending region.

33. The PCB of claim 32, wherein the bending region comprises a first opening adjacent to a first edge thereof, and a second opening adjacent to a second edge thereof opposite to the first edge.

34. The PCB of claim 32, wherein the at least one guard pattern comprises a first guard pattern on a top surface of the base substrate and a second guard pattern on a bottom surface of the base substrate.

35. The PCB of claim 32, wherein the at least two portions comprise at least two device mounting portions configured to mount one or more devices, the one or more devices being electrically connected via the connection line.
